(19) United States
(12) Patent Application Publication
(10) Pub. No.: US 2012/0130661 A1
(43) Pub. Date: May 24, 2012

(54) BATTERY MONITORING DEVICE AND BATTERY MONITORING METHOD

(75) Inventors: Hitoshi HAGIMORI, Tokyo (JP); Mitsuhiro Takahashi, Tokyo (JP)

(73) Assignee: MITSUMI ELECTRIC CO., LTD., Tokyo (JP)

(21) Appl. No.: 13/300,751

(22) Filed: Nov. 21, 2011

(30) Foreign Application Priority Data
Nov. 22, 2010 (JP) 2010-260657

(51) Int. Cl. G01R 31/36

(52) U.S. Cl. 702/63

(57) ABSTRACT

A battery monitoring device includes a detecting unit which detects a voltage value, a current value and a temperature of a secondary battery, a charging time computing unit which computes a charging time of the battery by using the voltage value, the current value and the temperature detected by the detecting unit, and a determining unit which determines a charging state of the battery. The charging time computing unit is configured to compute a fully charged time of the battery based on a first charging ratio, a constant-current charging ratio, and a second charging ratio.

### CROSS-REFERENCE TO RELATED APPLICATION

This application is based upon and claims the benefit of priority of Japanese patent application No. 2010-260657, filed on Nov. 22, 2010, the entire contents of which are incorporated by reference herein.

### BACKGROUND OF THE INVENTION

1. Field of the Invention

The present disclosure relates to a battery monitoring device and a battery monitoring method.

2. Description of the Related Art

Conventionally, a constant-current, constant-voltage (CC/CV) charging method is known as a method of charging a secondary battery, such as a lithium ion battery, which is used in an electronic device, such as a cellular phone. In the constant-current, constant-voltage charging method, constant-current (CC) charging is first performed, and if a voltage of the secondary battery reaches a predetermined voltage, the CC charging is switched to constant-voltage (CV) charging and the CV charging is subsequently performed, and if a charging current falls to a predetermined current value, it is detected that the battery reaches a fully charged level, and supply of the charging current is stopped.

In the CC/CV charging method described above, a charging time computation method to compute a charging time for the secondary battery during the charging to reach a fully charged level, based on the measured battery voltage value and charging current value is known. For example, see Japanese Laid-Open Patent Publication No. 07-274408.

However, in the charging time computation method disclosed in Japanese Laid-Open Patent Publication No. 07-274408, changes in the charging voltage, the charge end current, and the path resistance of a detection portion due to the environmental condition during the charging are not taken into consideration. Hence, there has been a problem that, if there is a change in the environmental condition (such as temperature), the accuracy of computation of the charging time becomes worse.

Generally, a permissible charging capacity of a secondary battery is varied depending on the charging temperature or the degradation ratio of the secondary battery. However, conventionally, the charging time is computed by using the permissible charging capacity of the battery computed at a time of the previous charging. Hence, there has been a problem that an error between the computed charging time and the measured charging time is too large.

### SUMMARY OF THE INVENTION

In one aspect, the present disclosure provides a battery monitoring device which is capable of computing a permissible charging capacity according to the state of the secondary battery and improving the accuracy of computation of the fully charged time of the secondary battery.

In an embodiment which solves or reduces one or more of the above-described problems, the present disclosure provides a battery monitoring device including: a detecting unit to detect a voltage value, a current value and a temperature of a secondary battery; a charging time computing unit to compute a charging time of the battery by using the voltage value, the current value and the temperature detected by the detecting unit; and a determining unit to determine a charging state of the battery, wherein the charging time computing unit is configured to compute a charging time of the battery based on a first charging ratio, a constant-current charging ratio and a second charging ratio, the first charging ratio corresponding to a predetermined charge end current and being computed by using a path resistance of the battery computed based on the voltage and current values detected by the detecting unit during constant-voltage charging of the battery, a charging voltage value of the battery, and an internal resistance value at a present temperature of the battery, the constant-current charging ratio being computed by using the first charging ratio, and the second charging ratio corresponding to a charge end current specific to a charging circuit to charge the battery and being computed by using the first charging ratio.

In an embodiment which solves or reduces one or more of the above-described problems, the present disclosure provides a battery monitoring method performed by a battery monitoring device including a detecting unit to detect a voltage value, a current value and a temperature of a secondary battery, a charging time computing unit to compute a charging time of the battery by using the voltage value, the current value and the temperature detected by the detecting unit, and a determining unit to determine a charging state of the battery, the battery monitoring method including: acquiring a path resistance of the battery based on the voltage and current values detected by the detecting unit during constant-voltage charging of the battery; computing a first charging ratio corresponding to a predetermined charge end current by using the acquired path resistance of the battery, a charging voltage value of the battery, and an internal resistance value at a present temperature of the battery; computing a constant-current charging ratio by using the first charging ratio; computing a second charging ratio corresponding to a charge end current specific to a charging circuit to charge the battery by using the first charging ratio; and computing a fully charged time of the battery based on the first charging ratio, the constant-current charging ratio and the second charging ratio.

Other objects, features and advantages of the present disclosure will be apparent from the following detailed description when read in conjunction with the accompanying drawings.

### BRIEF DESCRIPTION OF THE DRAWINGS

FIG. 1 is a block diagram showing the composition of a battery monitoring system of an embodiment of the present disclosure.

FIGS. 2A and 2B are diagrams for explaining a constant-voltage charging voltage.

FIG. 3 is a block diagram showing the composition of a monitoring IC which performs the process of computation of a fully charged time.

FIG. 4 is a flowchart for explaining the process of computation of a fully charged time of a secondary battery.

FIG. 5 is a diagram for explaining changes of the processing state used in the computation of a fully charged time of a secondary battery.

FIG. 6 is a flowchart for explaining the process of measurement of a path resistance Rc used in the computation of a fully charged time.

FIG. 7 is a diagram for explaining the characteristics of a first charging ratio SOCfull to a path resistance Rc and a resistance Rrtn at the present temperature.

FIG. 8 is a diagram showing the characteristics of a constant-current charge ratio SOCcc to an internal resistance Rrtn of a secondary battery.

FIG. 9 is a flowchart for explaining the process of computation of a constant-current charging time Tcc.

FIGS. 10A and 10B are diagrams for explaining a second charging ratio SOCchg used in the computation of a constant-voltage charging time Tcv.

FIG. 11 is a diagram showing changes of a charging current value Ic during the constant-voltage charging.

FIG. 12 is a diagram showing the characteristics of the right-hand side term to the left-hand side term Istart/Istop.

FIG. 13 is a flowchart for explaining the process of computation of a constant-current, constant-voltage charging time.

FIG. 14 is a diagram showing the gradient of a detection voltage and a detection current in the constant-current, constant-voltage charging method.

FIGS. 15A and 15B are diagrams for explaining a threshold for determining the constant-current charging or the constant-voltage charging.

FIGS. 16A and 16B are diagrams showing the state of a charging current and a charging voltage when a minute short circuit occurs during the constant-current, constant-voltage charging.

FIG. 17 is a diagram showing the state of the constant-voltage charging current at the charge end stage.

FIG. 18 is a flowchart for explaining the process of determination of a charging state.

FIGS. 19A and 19B are diagrams showing the characteristics between the constant-voltage charging current and the elapsed time at a charge end stage of a lithium ion battery at 25 degrees C.

FIG. 20 is a diagram showing the relationship between the elapsed times T1 and T2 and the corresponding charging current values I1 and I2 as in FIG. 19A.

FIG. 21 is a flowchart for explaining the process of charge end correction.

FIGS. 22A and 22B are diagrams for explaining the accuracy of computation of the estimated time computed by a charging time computing unit.

FIG. 23 is a diagram for explaining the accuracy of computation of a charging time corrected by a charge end correction unit.

FIG. 24 is a diagram for explaining changes of the computed time by switching of the charging time computation.

FIG. 25 is a diagram for explaining a modification of the process of charge end correction of this embodiment.

### DETAILED DESCRIPTION OF PREFERRED EMBODIMENTS

A description will be given of embodiments of the present disclosure with reference to the accompanying drawings.

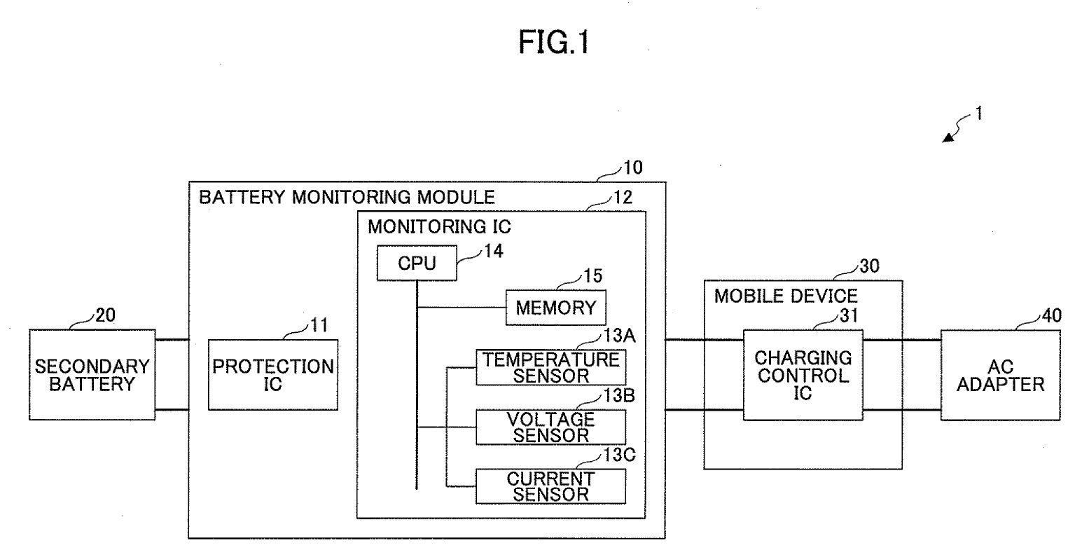

FIG. 1 is a block diagram showing the composition of a battery monitoring system of an embodiment of the present disclosure.

As shown in FIG. 1, the battery monitoring system 1 is constructed to include a battery monitoring module 10 (which is a battery monitoring device of an embodiment of the present disclosure), a secondary battery 20, a mobile device body 30, and an AC adaptor 40.

The battery monitoring module 10 has a function to monitor a charging state of the secondary battery 20. The battery monitoring module 10 includes a protection IC 11 and a monitoring IC 12.

The protection IC 11 detects an overcharge, an overdischarge, etc., of the secondary battery 20 to protect the secondary battery 20 from damages. The monitoring IC 12 is constructed to include a temperature sensor 13A to detect an ambient temperature of the secondary battery 20, a voltage sensor 13B to detect a charging voltage of the secondary battery 20, a current detection sensor 13C to detect a charging/discharging current of the secondary battery 20, a CPU 14 to control the current computation or the like based on the values output from the respective sensors, and a memory 15 to store the battery characteristic parameters of the secondary battery 20 used for the computation operation performed by the monitoring IC 12.

The monitoring IC 12 has the above composition and computes the remaining capacity of the secondary battery 20 based on the voltage and the current values, etc. of the secondary battery 20. The monitoring IC 12 computes an internal resistance value of the secondary battery 20 based on the ambient temperature and the remaining capacity of the secondary battery 20, and computes a permissible charging capacity, a fully charged time, etc. according to the state of the secondary battery 20 based on the capacity retention, the internal resistance value, the charging current, and the battery characteristic parameter of the secondary battery 20.

The secondary battery 20 is a chargeable and dischargeable battery. For example, the secondary battery 20 is a lithium ion battery, etc.

The mobile device body 30 is formed by a mobile phone, for example. The mobile device body 30 includes a charge control IC 31 which controls charging of the secondary battery 20 based on the values acquired from the monitoring IC 12.

The AC adaptor 40 converts the externally supplied alternating current power into a direct current power and supplies the resulting direct current power to the mobile device body 30.

Next, a path resistance of a charging/discharging path and a constant-voltage (CV) charging voltage used for the computation of a fully charged time in the battery monitoring system 1 described above will be described.

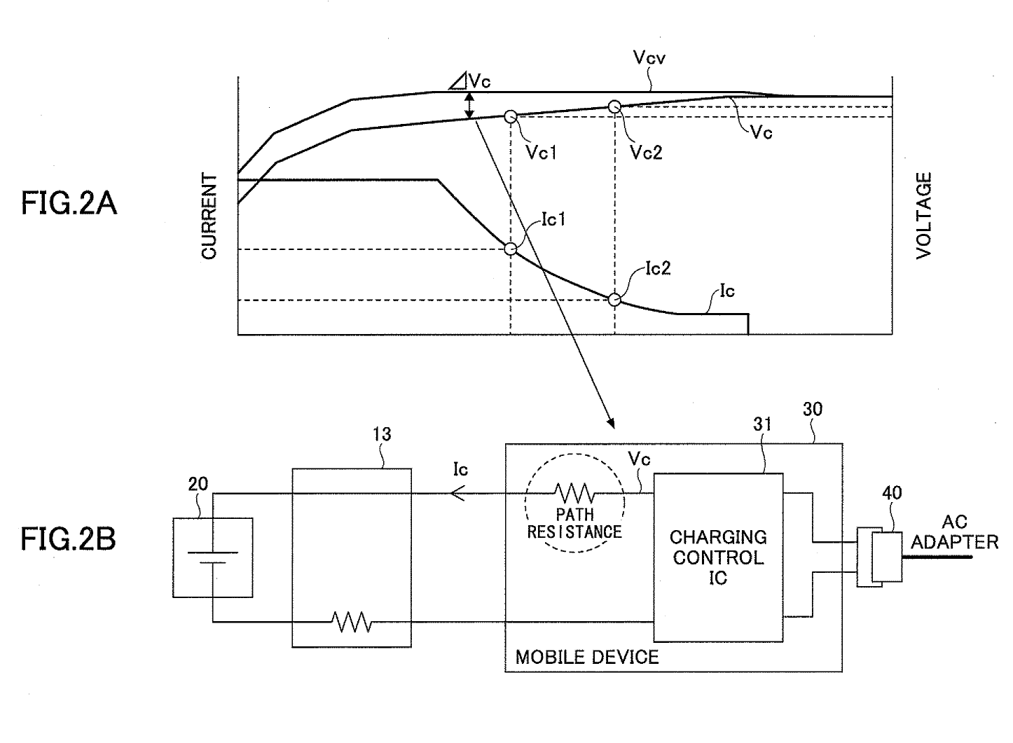

FIGS. 2A and 2B are diagrams for explaining a constant-voltage charging voltage. FIG. 2A shows the relationship between the constant-voltage charging voltage Vcv, the constant-voltage charging current Ic, and the output voltage Vc to the elapsed time. FIG. 2B shows a simplified composition of the battery monitoring system of FIG. 1.

As shown in FIG. 2A, the constant-voltage charging voltage Vcv to charge the secondary battery 20 is varied according to the output voltage Vc output from the charge control IC 31 shown in FIG. 2B, the path resistance Rc, and the constant-voltage charging current Ic. Specifically, the constant-voltage charging voltage Vcv is increased from the output voltage Vc by ΔVc which is represented by the product of the path resistance Rc and the constant-voltage charging current Ic. The path resistance Rc may be computed by using the values of Vc1, Vc2, Ic1 and Ic2 at two points in the constant-voltage charging as shown in FIG. 2A.

As described above, although the constant-voltage charging voltage Vcv with an voltage increment due to the path resistance Rc is undetectable by using the voltage sensor 13B, the voltage increment ΔVc due to the path resistance Rc can be considered as being the product of the path resistance Rc and the constant-voltage charging current Ic by the voltage increment.

Therefore, in this embodiment, the constant-voltage charging voltage Vcv is computed using the values of the constant-voltage charging current Ic2, the constant-voltage charging voltage Vc2, and the path resistance Rc which are acquired when computing the path resistance Rc. The process of computation of the path resistance Rc and the constant-voltage charging voltage Vcv will be described later.

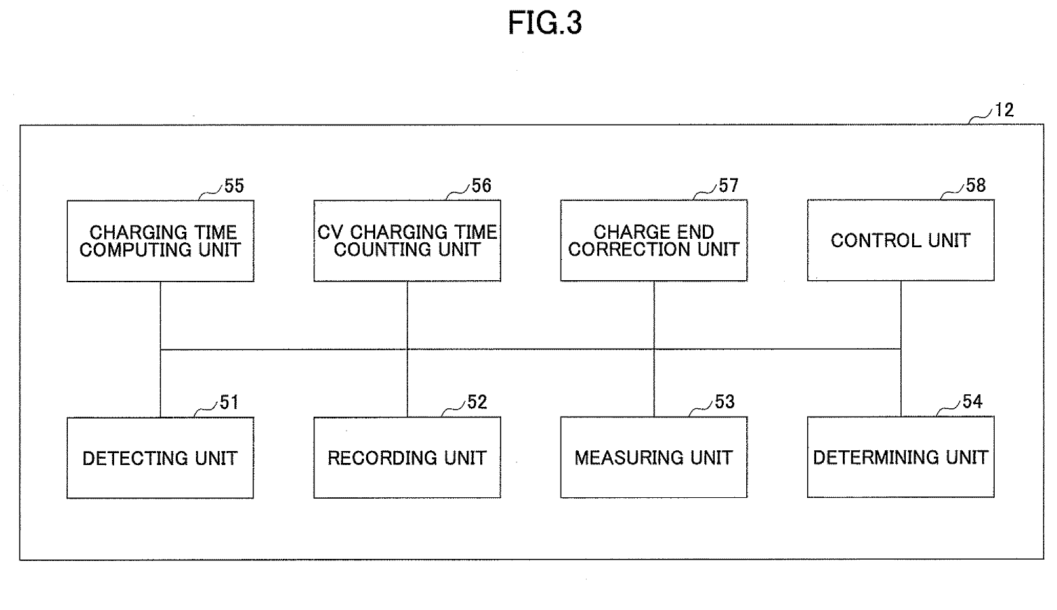

Next, the composition of the monitoring IC 12 to perform the process of computation of a fully charged time will be described. FIG. 3 is a diagram showing the composition of the monitoring IC which performs the process of computation of a fully charged time.

As shown in FIG. 3, the monitoring IC 12 is constructed to include a detecting unit 51, a recording unit 52, a measuring unit 53, a determining unit 54, a charging time computing unit 55, a constant-voltage charging time counting unit 56, a charge end correction unit 57, and a control unit 58.

The detecting unit 51 detects a temperature of a secondary battery 20, a charging voltage value Vc, and a charging current value Ic. The detecting unit 51 corresponds to the temperature sensor 13A, the voltage sensor 13B, and the current sensor 13C of the monitoring IC 12 described above.

The recording unit 52 is a memory, such as a ROM (read only memory). The recording unit 52 stores the battery characteristic parameters of the secondary battery 20 used for the process of computation of a fully charged time performed by the charging time computing unit 55.

The measuring unit 53 computes the path resistance Rc using the values detected by the detecting unit 51. The measuring unit 53 measures a voltage change rate and a current change rate, for example, when the value of the charging current value Ic detected by the detecting unit 51 meets the condition “Ic>0”.

The determining unit 54 determines a charging state of the secondary battery 20 in order to determine the timing to perform the process which computes the fully charged time. For example, the determining unit 54 acquires, from the recording unit 52, the voltage change rate and the current change rate measured by the measuring unit 53 and the predetermined charging current value Ic detected by the detecting unit 51, and determines the charging state of the secondary battery 20 based on the acquired values.

Hence, even in a case where a minute short circuit occurs during the constant-current, constant-voltage charging, the determining unit 54 is able to correctly determine the charging state of the secondary battery 20. The process of determination performed by the determining unit 54 will be described later.

The charging time computing unit 55 computes a constant-current charging time and a constant-voltage charging time when the charging state of the secondary battery 20 is determined as being the constant-current charging by the determining unit 54. In this embodiment, the fully charged time (the constant-current, constant-voltage charging time), which is an estimated time, is computed by totaling the computed constant-current charging time and the computed constant-voltage charging time.

For example, the charging time computing unit 55 computes the fully charged time of the secondary battery 20 based on a first charging ratio and a second charging ratio. The first charging ratio is a charging ratio to a battery capacity of the secondary battery 20 which is computed corresponding to a predetermined charge end current by using the path resistance Rc measured by the measuring unit 53 based on the values detected by the detecting unit 51 during the constant-voltage charging, the charging voltage Vcv of the secondary battery 20, and the internal resistance value at the present temperature of the secondary battery 20. The second charging ratio is computed corresponding to a charge end current specific to the charging circuit which charges the secondary battery 20, by using the first charging ratio and the CC charging ratio computed using the first charging ratio.

Specifically, the charging time computing unit 55 computes a constant-current charging time based on the first charging ratio and the charging current value detected by the detecting unit 51 during the constant-current charging, computes a constant-voltage charging time based on the second charging ratio, the CC charging ratio, and the charging current value detected by the detecting unit 51 during the constant-current charging, and computes a fully charged time of the secondary battery 20 by adding the constant-voltage charging time to the constant-current charging time.

The process of computation of the constant-current charging time and the process of computation of the constant-voltage charging time by the charging time computing unit 55 will be described later.

The constant-voltage charging time counting unit 56 counts down the constant-current, constant-voltage charging time computed by the charging time computing unit 55, when the charging state of the secondary battery 20 is determined as being the constant-voltage charging by the determining unit 54. Specifically, the constant-voltage charging time counting unit 56 performs a subtraction process to subtract the time corresponding to the elapsed time from the constant-current, constant-voltage charging time until the process of the charge end correction unit 57 (which will be described later) is performed.

When the charging state of the secondary battery 20 is determined as being a constant-voltage charging state by the determining unit 54 and the charging current value detected by the detecting unit 51 is below a predetermined value, the charge end correction unit 57 computes a charge end time by using the predetermined current value detected by the detecting unit 51 and the charge end current specific to the charging circuit which charges the secondary battery 20, and performs a correction process to count down from the computed charge end time.

Hence, the charge end correction unit 57 may output the estimated remaining time with good accuracy which is obtained from the constant-current, constant-voltage charging time computed by the charging time computing unit 55 and subtracted by the constant-voltage charging time counting unit 56.

The control unit 58 controls the respective components in the functional composition of the monitoring IC 12 and corresponds to the CPU 14. Specifically, the control unit 58 performs control processes for performing the process of computation of the fully charged time in this embodiment by using the respective functional components described above.

The control unit 58 may be arranged to determine the battery state of the secondary battery 20, by comparing the first charging ratio and the constant-current, constant-voltage charging time which are computed by the charging time computing unit 55, with the charging capacity and the charging time corresponding to the measured first charging ratio. The control unit 58 may be arranged to compute the battery resistance of the secondary battery 20 based on the measured permissible charging capacity of the secondary battery 20.

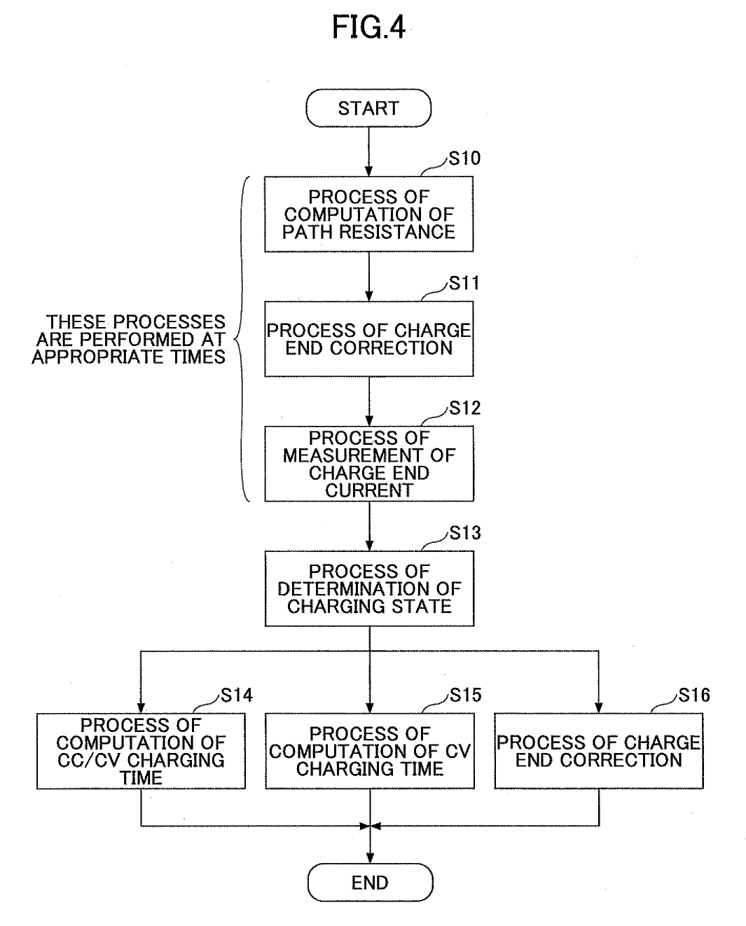

Next, the process of computation of the fully charged time of the secondary battery 20 performed by the above-described battery monitoring device 10 will now be described. FIG. 4 is a flowchart for explaining the process of computation of the fully charged time of the secondary battery.

As shown in FIG. 4, the measuring unit 53 performs the process of computation of a path resistance which computes the path resistance Rc of the secondary battery 20 using the voltage value and the current value of the secondary battery 20 which are beforehand detected by the detecting unit 51 during the constant-voltage charging (S10).

When a predetermined current value of the secondary battery 20 is detected by the detecting unit 51 during the constant-voltage charging, the charge end correction unit 57 performs the charge end correction process which corrects the charge end time (S11).

The measuring unit 53 performs the process of measurement of the charge end current which measures a charge end current of the secondary battery among the constant-voltage charging currents of the secondary battery 20 detected by the detecting unit 51 (S12).

Before the predetermined current is detected by the detecting unit 51 and the constant-current, constant-voltage charging of the secondary battery 20 is started, the measuring unit 53 performs the processing of steps S10-S12 described above at predetermined timing, and stores the values acquired by the respective processes into the recording unit 53.

Subsequently, when the constant-current, constant-voltage charging of the secondary battery 20 is started, the determining unit 54 performs the process of determination of the charging state (S13).

When it is determined at the step S13 that the voltage change rate is above a predetermined value (a first threshold) and the current change rate is below a predetermined value (a second threshold), the charging state is determined as being a constant-current charging state by the determining unit 54. Then, the process of computation of the constant-current, constant-voltage charging time is performed to compute the constant-current, constant-voltage charging time (314).

When it is determined at the step S13 that the voltage change rate is below the predetermined value (the first threshold) and the current change rate is above the predetermined value (the second threshold), the charging state is determined as being a constant-voltage charging state by the determining unit 54. Then, the process of computation of the constant-voltage charging time is performed to perform the subtraction process in which the constant-voltage charging time is subtracted (S15).

When it is determined at the step S13 by the determining unit 54 that the voltage change rate and the current change rate are below predetermined values (the first threshold, the second threshold) and the constant-voltage charging current is below a predetermined value (a third threshold), the charge end correction process is performed (S16).

In the flowchart shown in FIG. 4, one of the steps S14-S16 is selectively performed in accordance with the result of the determination process at the step S13.

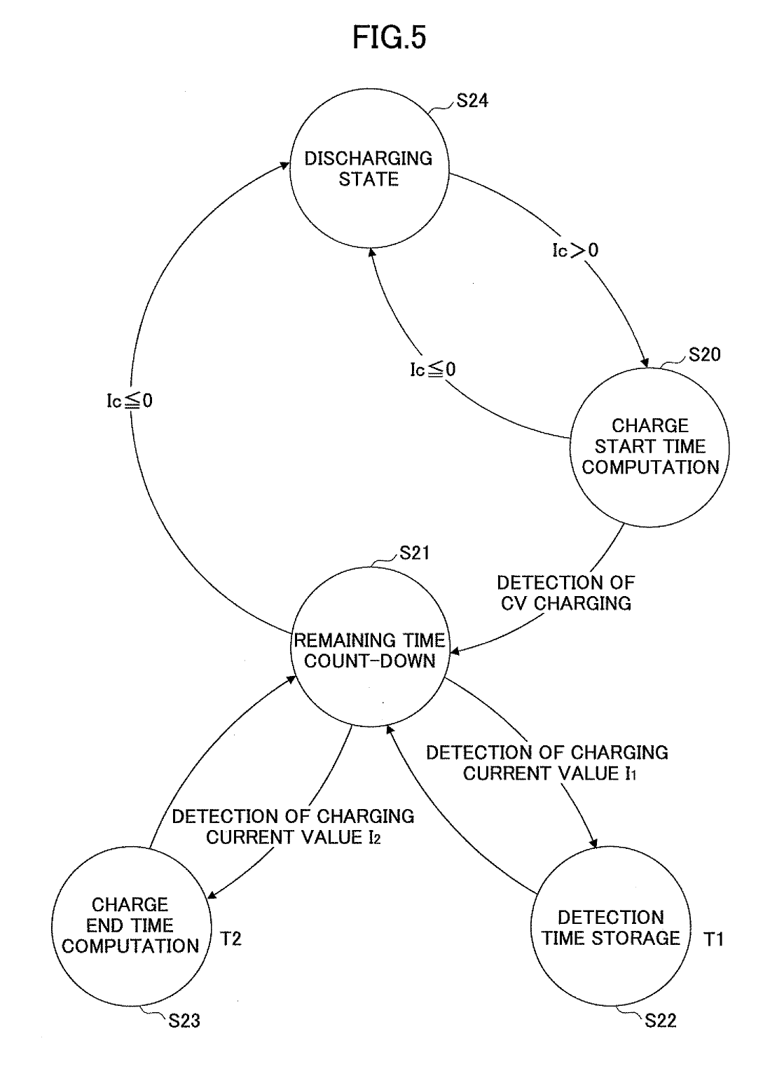

Next, changes of the processing state used in the computation of the fully charged time of the secondary battery 20 in this embodiment will be described. FIG. 5 is a diagram for explaining changes of the processing state used in the computation of the fully charged time of the secondary battery.

As shown in FIG. 5, for example, when the value of the charging current Ic of the secondary battery 20 detected by the detecting unit 51 is larger than 0 (Ic>0), it is determined that charging of the secondary battery 20 is started, and the processing state is changed to the constant-current, constant-voltage charging time computation (S20). For the sake of convenience, it is assumed that when the value of the charging current Ic of the secondary battery 20 detected by the detecting unit 51 is above 0 (+), the detected current indicates the charging current, and when the value of the charging current Ic detected by the detecting unit 51 is below 0 (−), the detected current indicates the discharging current.

In the state of S20, if the constant-voltage charging is detected, the processing state is changed to the remaining time count-down state in which the constant-current, constant-voltage charging time computed by the computation process of S20 is subtracted (S21). In the state of S21, if the predetermined current value Ic1 is detected, a detection time T1 at that time is stored (S22) and the processing state is returned to the state of S21.

Subsequently, in the state of S21, if the predetermined current value Ic2 is detected, a detection time T2 at that time is stored, and the processing state is changed to the charge end time computation using the detection times T1 and T2 (S23).

Subsequently, when the processing state is in the remaining time count-down state (S21) in which the charge end time computed in the state of S23 is subtracted and the value of the charging current of the secondary battery 20 is below zero, the processing state is changed to the discharging state (S24). In the state of S24, the case of Ic=0 is determined as being the fully charged state.

The computation process performed by the monitoring IC 12 to compute the fully charged time and the battery characteristic of the secondary battery 20 needed for the computation of the fully charged time will be described.

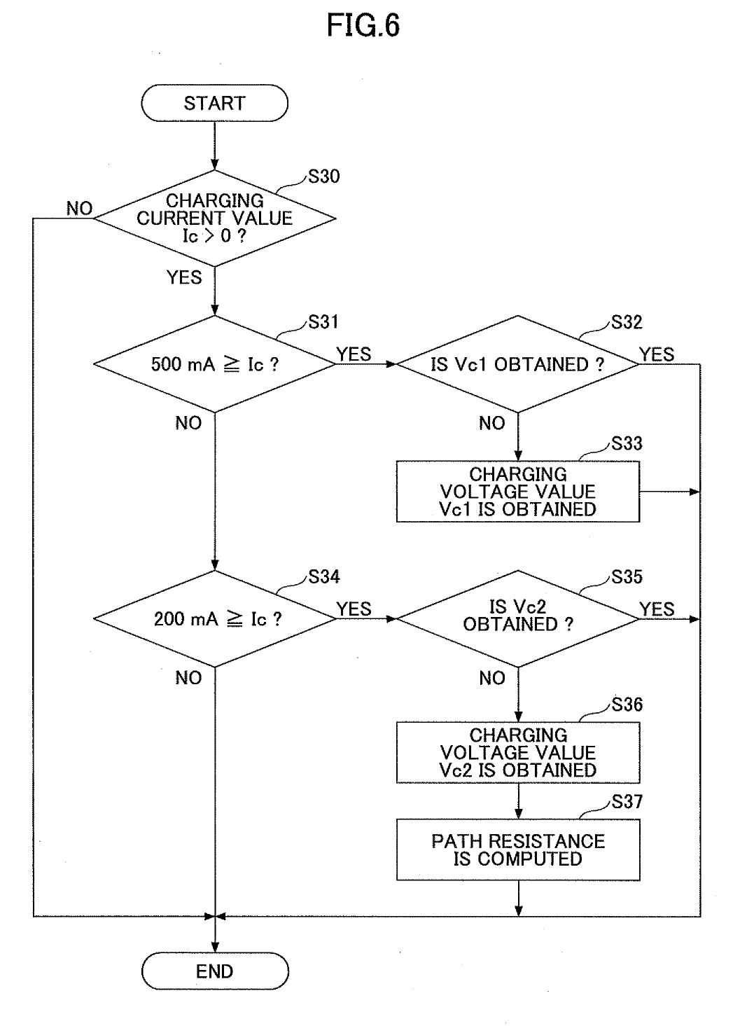

The process of measurement of the path resistance Rc used for the computation of the fully charged time will be described. FIG. 6 is a flowchart for explaining the process of measurement of the path resistance Rc used for the computation of the fully charged time.

In the following, specific numerical values at the steps in the flowcharts are given as examples, and it should be understood that the present disclosure is not limited to these values.

As shown in FIG. 6, the measuring unit 53 determines whether the charging current value Ic detected by the detecting unit 51 during the constant-voltage charging is above zero (Ic>0) (S30). When it is determined at S30 that the charging current value Ic is above zero, the measuring unit 53 determines whether the charging current value Ic is below 500 mA (Ic<=500 mA) (S31). When it is determined at S30 that the charging current value Ic is not above zero (Ic<=0), the process is terminated.

When it is determined at S31 that the charging current value Ic is below 500 mA, the measuring unit 53 determines whether the charging voltage value Vc1 at the time of Ic1=500 mA during the constant-voltage charging has been acquired (S32). When it is determined at S32 that the charging voltage value Vc1 has not been acquired, the measuring unit 53 acquires the charging voltage value Vc1 at the time of Ic1=500 mA (S33).

When it is determined at S31 that the charging current value Ic is not below 500 mA, the measuring unit 53 determines whether the charging current value Ic is below 200 mA (Ic<=200 mA) (S34). When it is determined at S34 that the charging current value Ic is below 200 mA, the measuring unit 53 determines whether the charging voltage value Vc2 at the time of Ic2=200 mA during the constant-voltage charging has been acquired (S35).

When it is determined at S35 that the charging voltage value Vc2 has not been acquired, the measuring unit 53 acquires the charging voltage value Vc2 at the time of Ic2=200 mA (S36).

Subsequently, the measuring unit 53 computes the path resistance based on the charging voltage value Vc2 acquired at 336, the charging voltage value Vc1 acquired at S33, and the corresponding charging current values Ic1 (500 mA) and Ic2 (200 mA) (S37). Then, the process is terminated.

When it is determined at S32 that the charging voltage value Vc1 has been acquired, or when it is determined at S35 that the charging voltage value Vc2 has been acquired, the process is terminated.

For example, at the above step S37, the measuring unit 53 may compute the path resistance Rc by using the following formula.

Rc=(Vc2−Vc1)/(Ic1−Ic2)

(Example)

Rc=(4180 mV−4168 mV)/(500 mA−200 mA)=0.04Ω

In addition, by using the path resistance Rc computed as described above, the measuring unit 53 may compute the constant-voltage charging voltage Vcv.

As previously described, the constant-voltage charging voltage Vcv including the voltage increment due to the path resistance Rc is undetectable by the detecting unit 51. Because the voltage increment ΔVc can be considered a product of the path resistance Rc and the constant-voltage charging current Ic, the constant-voltage charging voltage Vcv is computed by using the path resistance Rc, and the constant-voltage charging current Ic2 and the constant-voltage charging voltage Vc2 acquired when computing the path resistance Rc. For example, the constant-voltage charging voltage Vcv may be computed by using the following formula.

Vcv=Vc2+Ic2×Rc

Substituting specific numerical values into the above formula yields

Vcv=4180 mV+200 mA×0.04Ω=4188 mV.

The path resistance Rc and the constant-voltage charging voltage Vcv are computed whenever the charging takes place, and the values computed at the time of the previous computation are used for computation of the fully charged time.

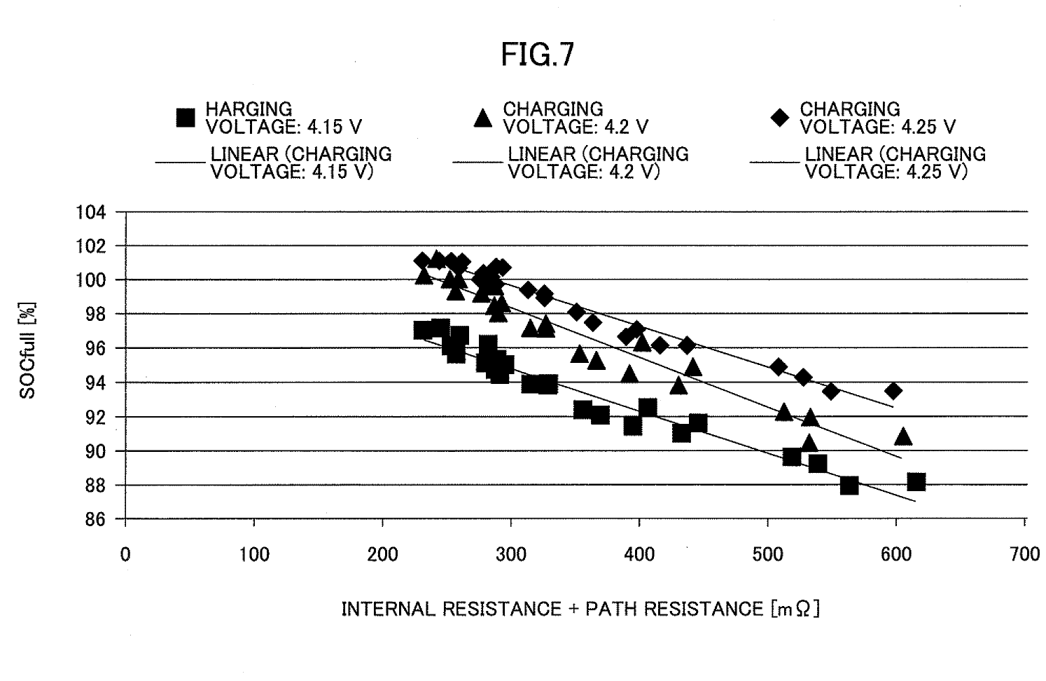

Next, the first charging ratio SOCfull used for computation of the fully charged time in this embodiment will be described with reference to FIG. 7.

It is necessary to compute the permissible charging capacity of the secondary battery 20 in the computation process of the fully charged time in this embodiment.

For example, if the SOC (state of charge) in which the charging is possible at the charge end current of 0 mA is called a first charging ratio SOCfull, the first charging ratio SOCfull has linear characteristics to the path resistance Rc plus the internal resistance value Rrtn at the present temperature, as shown in FIG. 7. The SOC described above indicates the ratio of the remaining capacity in the battery capacity of the secondary battery 20 (charging ratio).

FIG. 7 is a diagram showing the characteristics of the first charging ratio SOCfull to the path resistance Rc and the internal resistance value Rrtn at the present temperature. In FIG. 7, the horizontal axis (x-axis) denotes the total resistance in mΩ of the path resistance Rc and the internal resistance value Rrtn at the present temperature, and the vertical axis (y-axis) denotes the first charging ratio SOCfull in %.

As shown in FIG. 7, the first charging ratio SOCfull has the characteristics showing a certain offset to a predetermined charging voltage (for example, standard charging voltages 4.15V, 4.2V and 4.25V of the secondary battery 20).

If the characteristics shown in FIG. 7 are approximated by the linear term to the x-axis, the first charging ratio SOCfull may be represented by the following formula.

SOCfull=αSOC×(Rrtn+Rc)+βSOC+αV×ΔVcv (1)

(Example)

SOCfull=−0.026×(139 mΩ+100 mΩ)+105.5+0.05×(4250 mV−4200 mV)

In the above formula, ΔVcv is the voltage which is obtained by subtracting the standard charging voltage of the secondary battery 20 from the computed constant-voltage charging voltage Vcv (ΔVcv=Vcv−standard charging voltage (e.g. 4.2V)).

The coefficients (αSOC, βSOC, αV) which indicate the characteristics of SOCfull shown in FIG. 7 are stored in the recording unit 52 as the characteristic data.

When the charging current value Ic>0 is detected by the detecting unit 51, the charging time computing unit 55 determines that the processing state is in the charging state, and computes the first charging ratio SOCfull in accordance with the above formula (1) by using the voltage increment ΔVcv, the internal resistance value Rrtn at the present temperature, and the path resistance Rc (computed beforehand).

The internal resistance value Rrtn at the present temperature may be computed based the ambient temperature of the secondary battery 20 and the remaining capacity of the secondary battery 20 in accordance with a known computation method. For example, the internal resistance value Rrtn at the present temperature may be computed by the present resistance as ΔVc/ΔIc, where ΔIc is the current change when the charging is started from a stable state in which the charging or the discharging of the secondary battery 20 is not performed, and ΔVc is the voltage change before and after the charging is started. The internal resistance value Rrtn increases when the temperature falls, the temperature-characteristic formula representing such characteristics is predetermined, and the internal resistance Rrtn at the present temperature may be computed based on the previously computed internal resistance value and the temperature-characteristic formula.

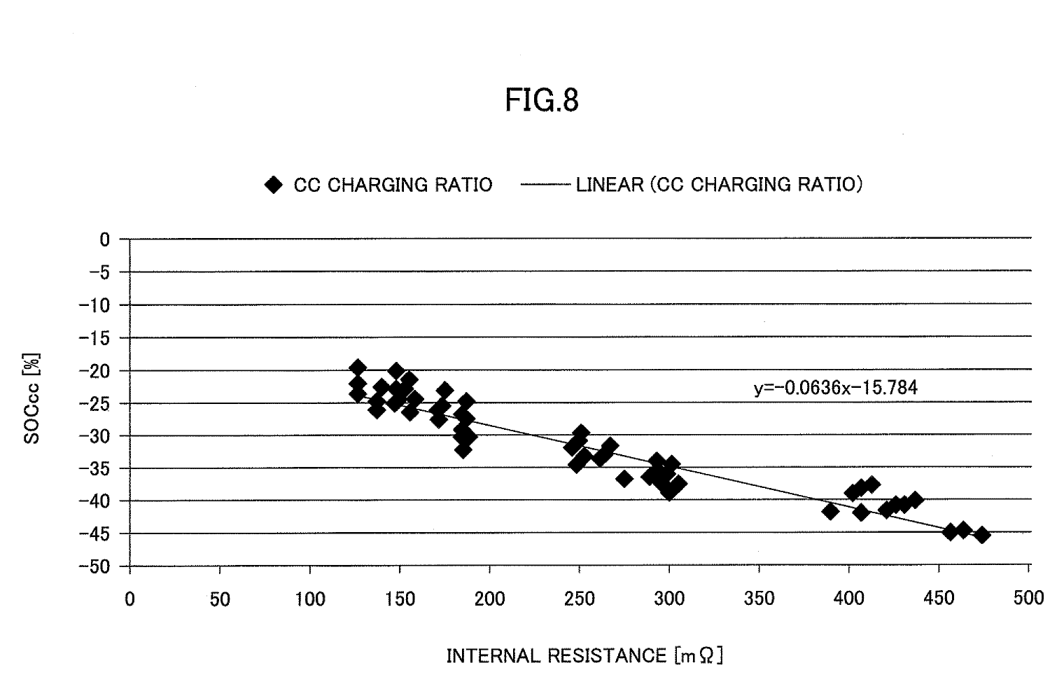

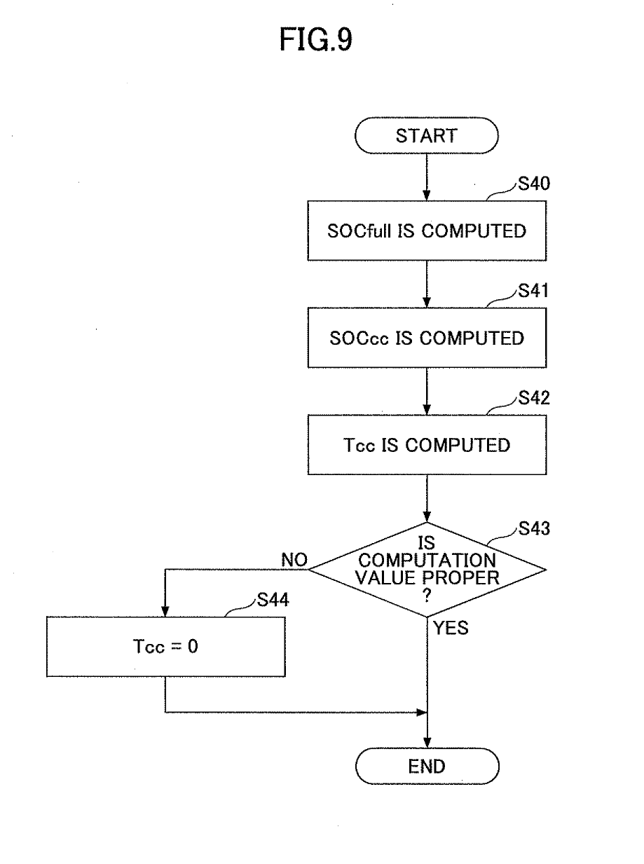

Next, the process of computation of a constant-current charging time Tcc will be described with reference to FIGS. 8 and 9.

First, a CC charging ratio SOCcc which is a charging ratio to the battery capacity of the secondary battery 20 by which the charging by the constant-current (CC) is possible, and which is used for computation of the constant-current charging time Tcc will be described.

The CC charging ratio SOCcc may be computed by the following formula. In computing the CC charging ratio SOCcc based on the first charging ratio SOCfull that is the charging upper limit of the secondary battery 20, the voltage drop by the resistance component and the change amount by the change of the charging voltage are taken into consideration.

SOCcc=SOCfull+(αR×Icc)/1000+αV×ΔVcv

Substituting specific numerical values into the above formula yields

SOCcc=101.8%+(−29×700 mA)/1000+0.05×(4250 mV−4200 mV)=84%.

In the above formula, Icc is the charging current value detected by the detecting unit 51 during the constant-current charging. In the above formula for computing the constant-current charging ratio SOCcc, the term (αR×Icc)/1000 represents the voltage drop by the resistance component, and the term αV×ΔVcv represents the change amount by the charging voltage change.

The resistance component coefficient αR used in the voltage drop by the resistance component may be decomposed into the component by the internal resistance of the secondary battery 20, and the component by the path resistance. Specifically, the resistance component coefficient αR may be represented by the following formula:

αR=f(Rrtn)+αV×RC.

The correction coefficient f(Rrtn) of the internal resistance of the secondary battery 20 may be represented by the following formula, by using the above formula of the constant-current charging ratio SOCcc and the above formula of the resistance component coefficient αR.

f(Rrtn)=(SOCcc−SOCfull−(αV×Rc×Icc)/1000−αV×ΔVcv)/Icc×1000

Substituting specific numerical values into the above formula yields

f(Rrtn)=(80%−99.4%−(0.05×100 mΩ×700 mA)/1000−0.0507×(4250 mV−4200 mV))/700 mA×1000=−34.05.

FIG. 8 is a diagram showing the characteristics of the constant-current charging ratio SOCcc to the internal resistance value Rrtn of the secondary battery. In FIG. 8, the horizontal axis (x-axis) denotes the internal resistance in mΩ, and the vertical axis (y-axis) denotes the constant-current charging ratio SOCcc in %. The vertical axis of FIG. 8 corresponds to the right-hand side term of the formula of the correction coefficient f(Rrtn) described above.

As shown in FIG. 8, the internal resistance value Rrtn of the secondary battery may be approximated as a linear relation to the value of the constant-current charging ratio SOCcc (the value of the right-hand side term described above).

If the characteristics shown in FIG. 8 are approximated by the linear term to the x-axis, the resistance component coefficient αR may be represented by the following formula.

αR=αcc×Rrtn+βcc−αV×Rc

Substituting specific numerical values into the above formula yields αR=−0.06×139 mΩ−15.875−0.05×100 mΩ=−29.

The constant-current charging time Tcc may be represented by the following formula.

Tcc={SOCfull+(αR×Icc)/1000+αV×ΔVcv×(battery capacity)/100−remaining capacity}/Icc×60 (2)

Substituting specific numerical values into the above-formula (2) yields

Tcc={101.8%+(−29×700 mA)/1000+0.05×(4250 mV−4200 mV)×998 mAh/100−22 mAh}/700 mA×60=69.9 min.

The coefficient values (αacc, βcc, αV) representing the characteristics described above are stored in the recording unit 52 as the characteristic data.

Next, FIG. 9 is a flowchart for explaining the process of computation of a constant-current charging time Tcc.

As shown in FIG. 9, the charging time computing unit 55 computes the first charging ratio SOCfull by the above formula (1) (S40), and computes the constant-current charging ratio SOCcc by using the first charging ratio SOCfull which is computed at the step S40 (S41).

Subsequently, the charging time computing unit 55 computes the constant-current charging time Tcc by the above formula (2) (S42), and determines whether the value of the computed constant-current charging time Tcc is appropriate (S43).

When the value of the constant-current charging time Tcc is set to Tcc<0, it is determined at S43 that the value is not appropriate. Then, the charging time computing unit 55 sets the value of the constant-current charging time Tcc to zero (Tcc=0) (S44), and the process is terminated.

On the other hand, when the value of the constant-current charging time Tcc is not set to Tcc<0, it is determined at S43 that the value is appropriate. Then, the process is terminated.

Specifically, after the first charging ratio SOCfull is computed at the step S40, the charging time computing unit 55 may compute the constant-current charging time Tcc at the step S43.

At this time, the charging time computing unit 55 acquires the characteristic data (αcc, βcc, αV) stored in the recording unit 52, and computes the constant-current charging time Tcc by the above formula (2) by using the CC charging current value Icc detected by the detecting unit 51, the path resistance Rc computed beforehand, the internal resistance value Rrtn at the present temperature, the first charging ratio SOCfull, the voltage increment ΔVcv due to the path resistance, the battery capacity and the remaining capacity corresponding to the standard charging voltage of the secondary battery 20.

The battery capacity and the remaining capacity described above are computed by using a known method. For example, the battery capacity may be computed based on the relationship between the battery capacity charged by the charging at a time and the charging ratio change at that time. Specifically, the battery capacity may be computed by using the formula: battery capacity mAh=charging capacity mAh/(charge-end charging ratio %−charge-start charging ratio %)×100.

In addition, the remaining capacity of the secondary battery 20 may be computed as follows. A table representing the relationship between the voltage and the charging ratio is stored beforehand in the recording unit 52. By accessing the table stored in the recording unit 52, the remaining capacity may be computed based on the table, the charging ratio, and the battery capacity described above, wherein the charging ratio is acquired from the table according to a detected voltage value of the battery in a stable state (in which the charging or the discharging is not performed and a voltage change is minute). Alternatively, the remaining capacity may be computed based on the integrated quantity of the charging or discharging current in the secondary battery 20.

In order to reflect the time jitter due to a temperature change and a charging current change, such as a change in the constant-current charging current value Icc, the constant-current charging time Tcc may be computed intermittently at intervals of a predetermined time until the charging state of the secondary battery 20 is determined as being a constant-voltage charging state by the determining unit 54.

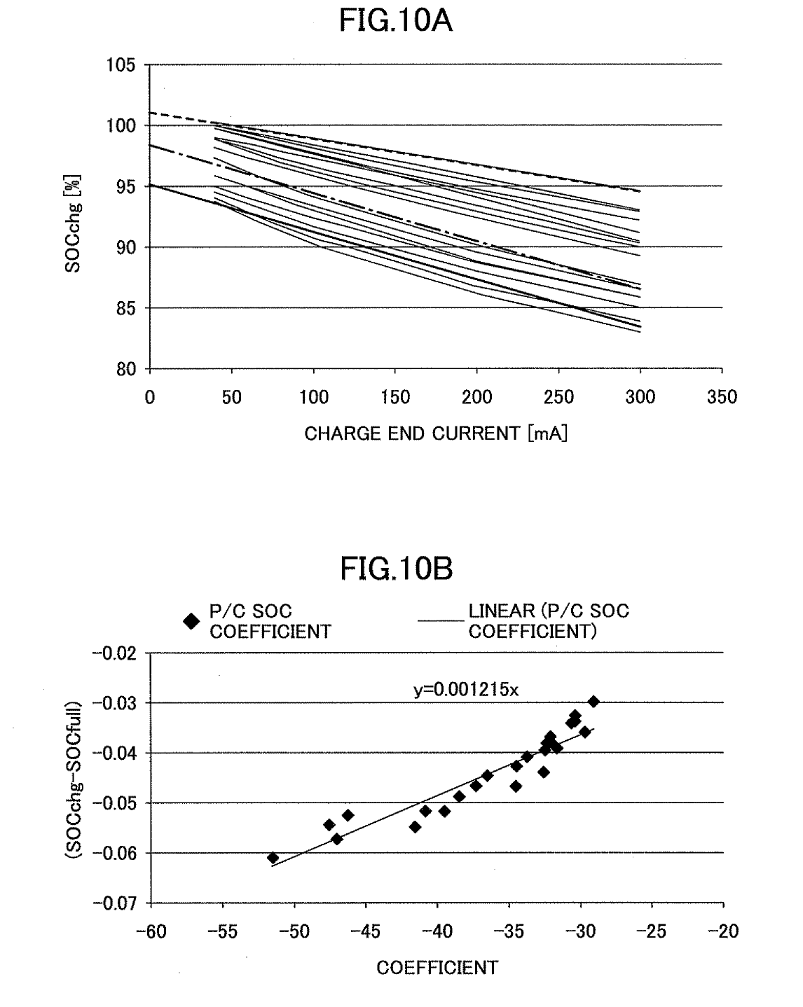

Next, the second charging ratio SOCchg used for computation of the constant-voltage charging time Tcv by the constant-voltage (CV) charging will be described. FIGS. 10A and 10B are diagrams for explaining the second charging ratio SOCchg used for computation of the constant-voltage charging time Tcv.

The second charging ratio SOCchg is a charging ratio computed corresponding to a charge end current value Istop which is specific to a charging circuit (for example, the Istop indicates a charge end current value used to stop charging of the secondary battery 20 in the charging circuit to charge the secondary battery 20 including the charge control IC 31). For example, as the charge end current value Istop, the latest charge end current value Istop detected at the last time of charging of the secondary battery 20 is stored in the recording unit 52, and the stored value is used at the following time of charging of the secondary battery 20.

FIG. 10A is a diagram showing the characteristics of the second charging ratio SOCchg to the charge end current Istop. In FIG. 10A, the horizontal axis (x-axis) denotes the charge end current in mA, and the vertical axis (y-axis) denotes the second charging ratio SOCchg in %. As shown in FIG. 10A, the plots indicate the relationship between the second charging ratio SOCchg and the charge end current Istop, and the second charging ratio SOCchg has a second-order characteristic to the charge end current Istop.

FIG. 10B is a diagram showing the relationship between the gradient (permissible changing (P/C) SOC coefficient) of the approximated straight line obtained by linear approximation of the characteristics shown in FIG. 10A, and the sum of the resistance component coefficient αR and the charging voltage ΔVcv obtained at the time of computation of the constant-current charging time Tcc. As shown in FIG. 10B, the gradient of the approximated straight line and the sum of the resistance component coefficient αR and the charging voltage ΔVcv show the linear characteristic which may be computed by approximation.

The characteristics shown in FIG. 10B are approximated by the linear term to the x-axis and it is assumed that the coefficient αchg changes according to the resistance value. The second charging ratio SOCchg may be represented by the following formula.

SOCchg=SOCfull+αchg(αR+αV×ΔVcv/Icc)×Istop (3)

Substituting specific numerical values into the above formula yields

SOCchg=101.8%+0.00119[−29+0.05×(4250 mV−4200 mV)/700 mA×60 mA=99.7%.

In FIG. 10B, the horizontal axis (x-axis) denotes the coefficient corresponding to (αR+αV×ΔVcv/Icc) of the above formula (3), and the vertical axis (y-axis) denotes the value of (SOCchg−SOCfull).

The value of the coefficient (a chg) of the above formula (3) which shows the above-described characteristics is stored in the recording unit 52 as characteristic data. After the first charging ratio SOCfull is computed, the charging time computing unit 55 acquires the value of the charge end current Istop and the value of the coefficient αchg stored in the recording unit 52, and computes the second charging ratio SOCchg according to the above formula (3) by using the first charging ratio SOCfull and the resistance component coefficient αR computed beforehand.

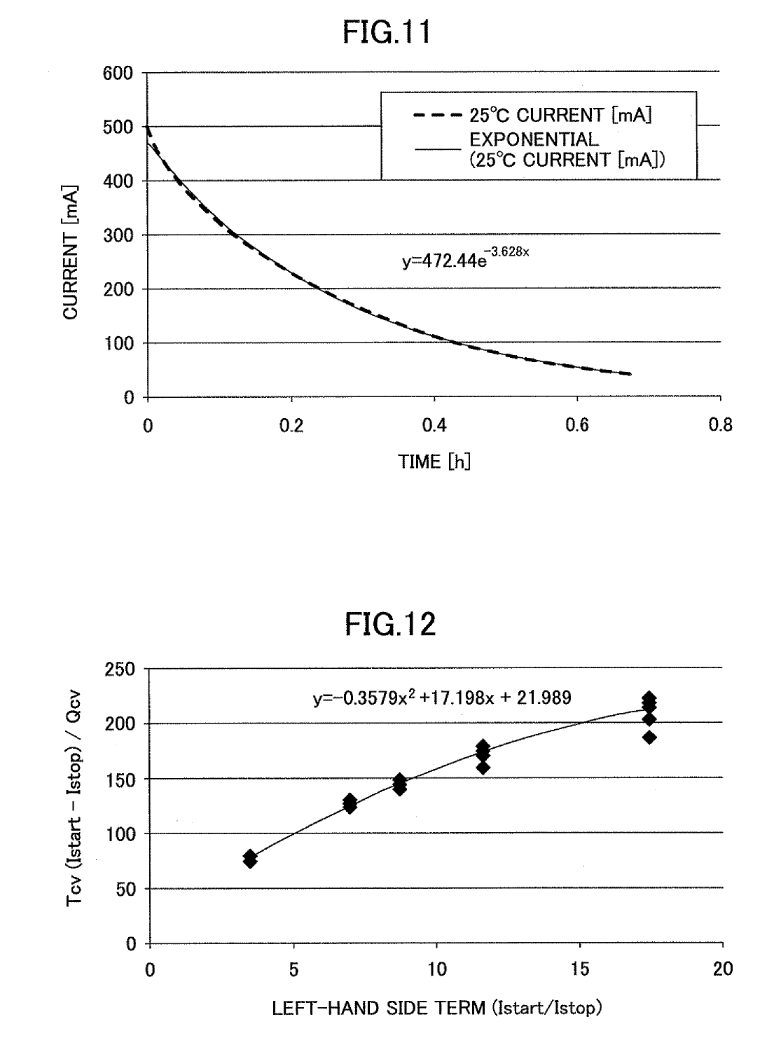

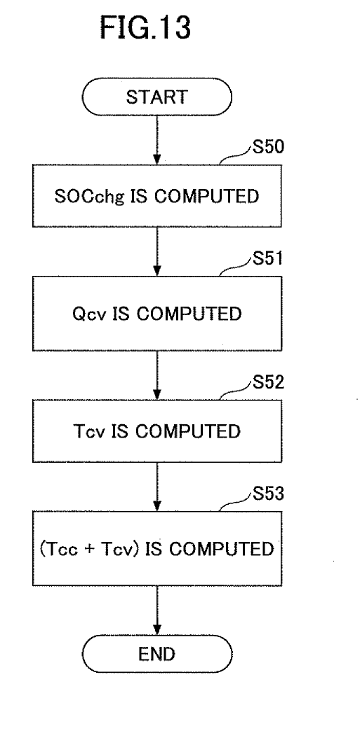

Next, the process of computation of the constant-voltage charging time Tcv will be described with reference to FIGS. 11 and 12. FIG. 11 is a diagram showing changes of the charging current value Ic during the constant-voltage charging. In FIG. 11, the horizontal axis (x-axis) denotes the time in hour, and the vertical axis (y-axis) denotes the charging current in mA.

As shown in FIG. 11, changes of the charging current Icy during the constant-voltage charging are expressed in a form of an exponential function. If it is assumed that the changes may be approximated by an exponential function, the constant-voltage charging time Tcv which is the time needed for the constant-voltage charging may be represented by the following formula:

Tcv=log(Istart/Istop)/(Istart−Istop)×Qcv

where Qcv is a permissible CV charging capacity.

Because it is difficult to implement the computation of a logarithmic function by the firmware, the computation part of log is replaced by a function f which is implemented as an approximation of the logarithmic function in the above formula. This function f may be represented by the following formula:

f(Istart/Istop)=Tcv×(Istart−Istop)/Qcv

where Qcv is a permissible CV charging capacity.

Substituting specific numerical values into the above formula yields

f(Istart/Istop)=42 min×(700 mA−60 mA)/(995 mAh−835 mAh)=11.7.

The parameter Istart described above shows the value of the constant-current charging current Icc at the time of computation. The permissible CV charging capacity Qcv may be expressed by using the CC charging ratio SOCcc and the second charging ratio SOCchg as follows:

Qcv=(SOCchg−SOCcc)×(battery capacity).

It can be understood that the following characteristics exist between the left-hand side term Istart/Istop and the right-hand side term of the above formula.

FIG. 12 is a diagram showing the characteristics of the right-hand side term to the left-hand side term Istart/Istop of the above formula. In FIG. 12, the horizontal axis (x-axis) denotes the value of the left-hand side term Istart/Istop of the above formula, and the vertical axis (y-axis) denotes the value of the right-hand side term Tcv×(Istart−Istop)/Qcv of the above formula. The “Qcv” on the vertical axis denotes the capacity value charged in the constant-voltage charging time Tcv.

As shown in FIG. 12, it can be understood that the right-hand side term has a second-order characteristic to the left-hand side term Istart/Istop. Hence, the characteristics shown in FIG. 12 are approximated by a second-order term to the x-axis. The constant-voltage charging time Tcv may be represented by the following formula.

Tcv=[αcv×(Icc/Istop)²+βcv×(Icc/Istop)+γcv]/(Icc−Istop)×Qcv=[αcv×(Icc/Istop)²+βcv×(Icc/Istop)+γcv]/(Icc−Istop)×(SOCchg−SOCcc)×(battery capacity) (4)

In the above formula (4), the charging current value Istart is represented by Istart=Icc.
Substituting specific numerical value into the above formula (4) yields

Tcv=[−0.193×(700 mA/60 mA)²+12.25×(700 mA/60 mA)+50.5]/(700 mA−60 mA)×(99.7%−84%)×998 mAh/100=41 min.

The coefficient values (αcv, βcv, γcv) which show the characteristics described above are stored in the recording unit 52 as characteristic data. After the second charging ratio SOCchg is computed, the charging time computing unit 55 acquires the charge end current Istop and the coefficient values (αcv, βcv, γcv) stored in the recording unit 52, and computes the constant-voltage charging time Tcv according to the above formula (4) by using the second charging ratio SOCchg, the CC charging ratio SOCcc computed beforehand, and the detected charging current value Icc.

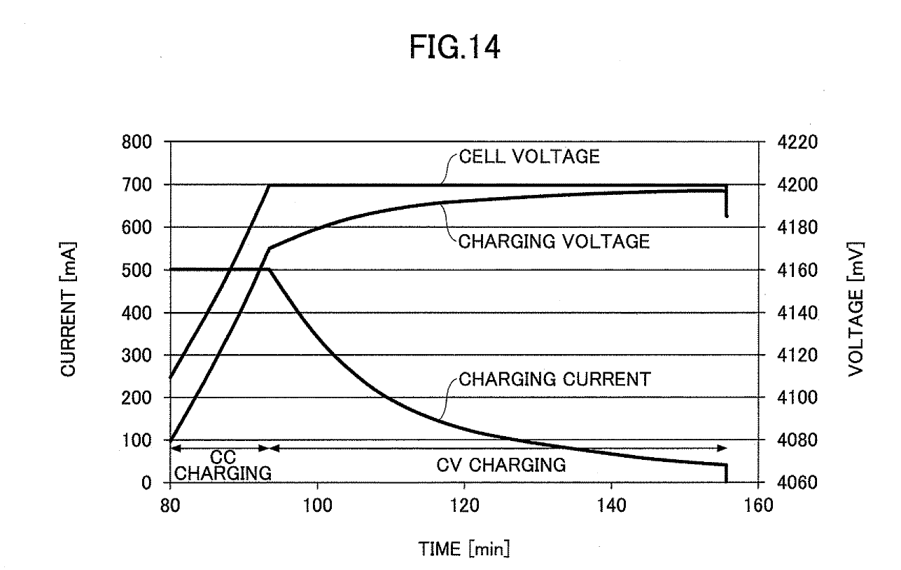

Next, FIG. 13 is a flowchart in which the process of computation of the constant-current, constant-voltage (CC/CV) charging time. As shown in FIG. 13, the charging time computing unit 55 computes the second charging ratio SOCchg by the above formula (3) (S50). The charging time computing unit 55 computes the permissible CV charging capacity Qcv by using the second charging ratio SOCchg computed at S50 and the CC charging ratio SOCcc computed beforehand, as described above (S51).

Subsequently, the charging time computing unit 55 computes the constant-voltage charging time Tcv by the above formula (4) (S52), and adds the constant-voltage charging time Tcv computed at S52 to the constant-current charging time Tcc which is previously computed and stored (S53). Then, the process of FIG. 13 is terminated.

As described above, the charging time computing unit 55 computes a total time of the constant-current charging time Tcc and the constant-voltage charging time Tcv, which have been computed according to the above formulas (1) to (4), as being an estimated fully charged time of the secondary battery 20.

In this embodiment, as described above, the total time of the constant-current charging time Tcc and the constant-voltage charging time Tcv is computed as the estimated fully charged time of the battery by the charging time computing unit 55 until the charging state of the secondary battery 20 is determined as being the constant-voltage charging state by the determining unit 54.

After the charging state of the secondary battery 20 is determined as being the constant-voltage charging state by the determining unit 54, the constant-voltage charging time counting unit 56 performs a countdown process which counts down the estimated fully charged time computed by the charging time computing unit 55.

Specifically, the constant-voltage charging time counting unit 56 performs a subtraction process which subtracts the elapsed time from the estimated fully charged time such that the estimated fully charged time is counted down, and continuously performs the countdown process until the correction process by the charge end correction unit 57 (which will be described later) is performed.

The countdown process may be performed by simple subtraction of the elapsed time from the estimated fully charged time, because it is unlikely that, during the constant-voltage charging, a large time variation takes place due to current changes.

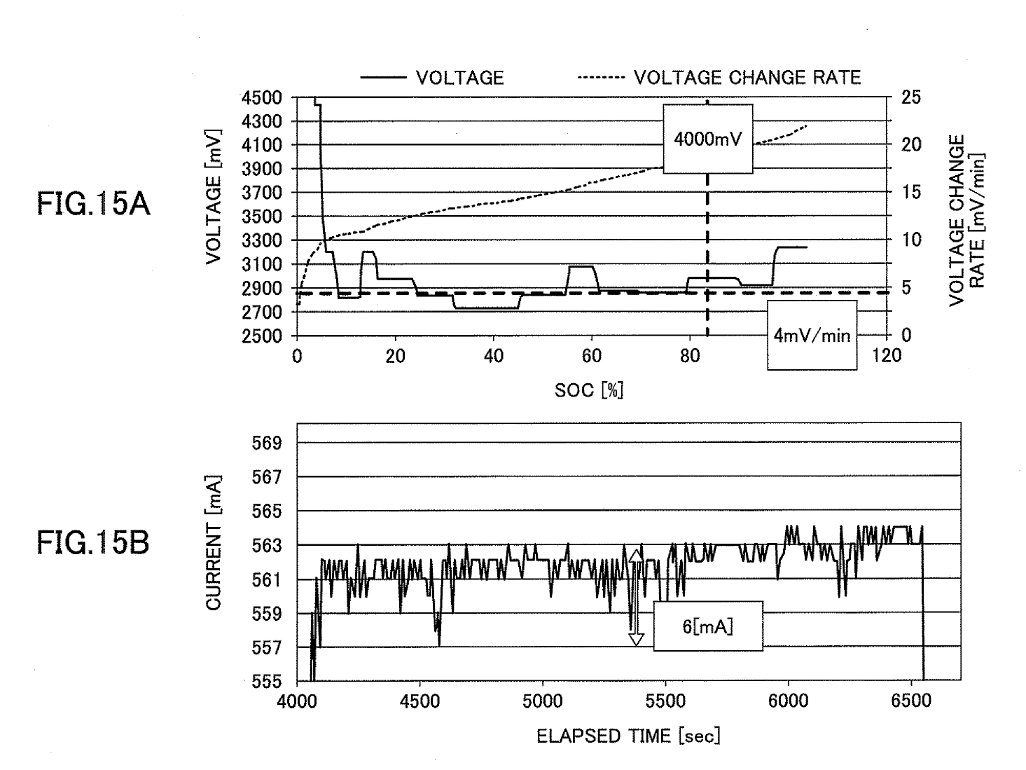

Next, in order to determine the timing to perform the respective computation processes for computing the estimated fully charged time of the secondary battery, the process of determination of a charging state of the secondary battery 20 performed by the determining unit 54 will be described with reference to FIGS. 14-17.

FIG. 14 is a diagram showing the gradient of a detection voltage and a detection current in the constant-current, constant-voltage charging method. In FIG. 14, the horizontal axis (x-axis) denotes the time in minute, the left-hand side vertical axis (y-axis) denotes the charging current in mA, and the right-hand side vertical axis (y-axis) denotes the charging voltage in mV.

The detection current shown in FIG. 14 is a charging current value of the secondary battery 20 detected by the detecting unit 51, the detection voltage shown in FIG. 14 is a charging voltage value of the secondary battery 20 detected by the detecting unit 51, and the cell voltage shown in FIG. 14 is a battery voltage of the secondary battery 20.

As shown in FIG. 14, during the constant-current (CC) charging, the detection current remains unchanged and is held at a fixed value, and the detection voltage increases with a predetermined constant gradient. During the constant-voltage (CV) charging, the detection voltage increases with a decreasing gradient and the detection current decreases exponentially. In the constant-current, constant-voltage charging, due to occurrence of a minute short-circuit in the cell of the secondary battery 20, a charging current change and a temperature change, the detection voltage during the constant-current charging is stabilized, and during the constant-voltage charging, the detection current is stabilized and the gradient of the detection current changes.

The determining unit 54 in this embodiment determines a charging state of the secondary battery 20 based on the threshold values which are predetermined by taking the above points into consideration. It is possible to determine the charging state of the secondary battery 20 correctly.

The constant-voltage charging voltage which is detected by the detecting unit 51 changes according to the path resistance Rc, the constant-voltage charging current, and the output voltage output from the charge control IC 31. Taking into consideration this matter, a determination start voltage as a threshold for determining a transition state between the CC charging state and the CV charging state is set up.

For example, when the lower limit of the constant-voltage charging voltage is set to 4150 mV, the path resistance Rc is set to 80 mΩ, and the constant-current charging current is set to 700 mA, the determination start voltage is set up using the following formula:

Determination start voltage=4150−(700×80)/1000=4094 mV.

As is apparent from the above example, the determination start voltage as the threshold for determining a transition state between the CC charging state and the CV charging state may be set up to be above a detection voltage of about 4000 mV.

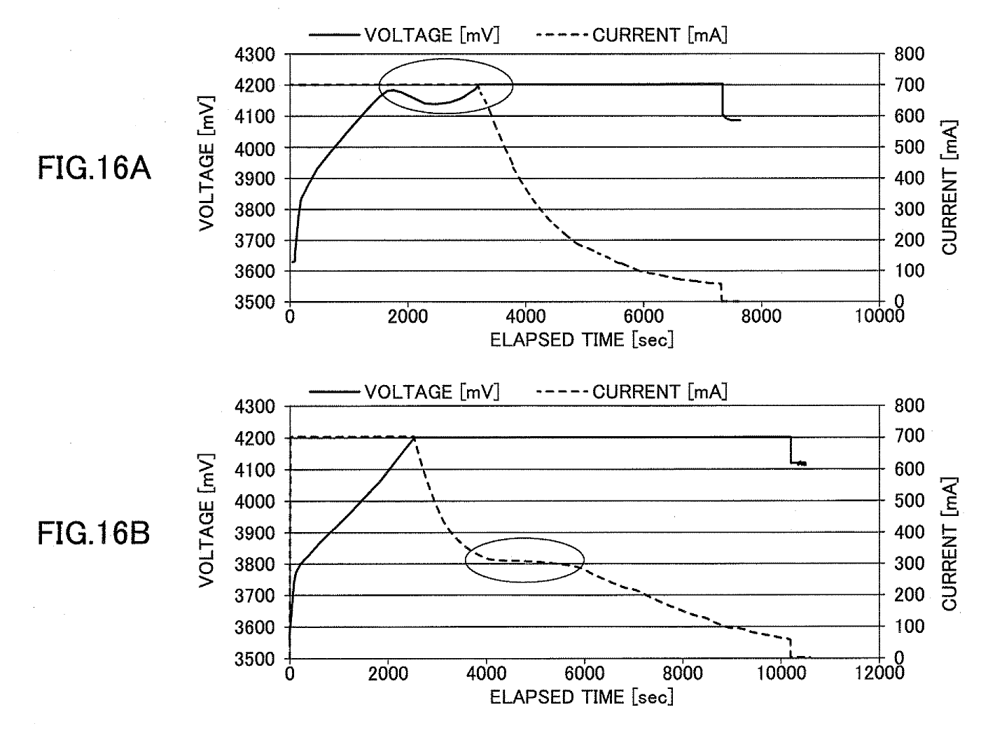

FIGS. 15A and 15B are diagrams for explaining the threshold for determining the constant-current charging state or the constant-voltage charging state. FIG. 15A is a diagram showing the case in which it is assumed that the voltage changes according to the OCV (open circuit voltage) table when the charging current is near an estimated minimum charging current of 330 mA. In FIG. 15A, the horizontal axis (x-axis) denotes the SOC in %, the right-hand side vertical axis (y-axis) denotes the voltage change rate in mV/min, and the left-hand side vertical axis (y-axis) denotes the charging voltage in mV.

As shown in FIG. 15A, when the charging voltage is above the determination start voltage of 4000 mV as the threshold for determining a transition state between the CC charging state and the CV charging state, the voltage change rate is above 4 mV/min. As apparent from FIG. 15A, the value 4 mV/min of the voltage change rate may be determined as a first threshold for determining the CC charging state or the CV charging state in this case.

FIG. 15B is a diagram for explaining the threshold for determining a stable current change rate apart from the variations in the charging current during the constant-current charging. In FIG. 15B, the horizontal axis (x-axis) denotes the elapsed time in seconds and the vertical axis (y-axis) denotes the charging current in mV.

As shown in FIG. 15B, the charging current during the constant-current charging is changed in a maximum amplitude of about 6 mA. As is apparent from FIG. 15B, the value 8 mA/min of the current change rate may be determined as a second threshold for determining the CC charging state or the CV charging state.

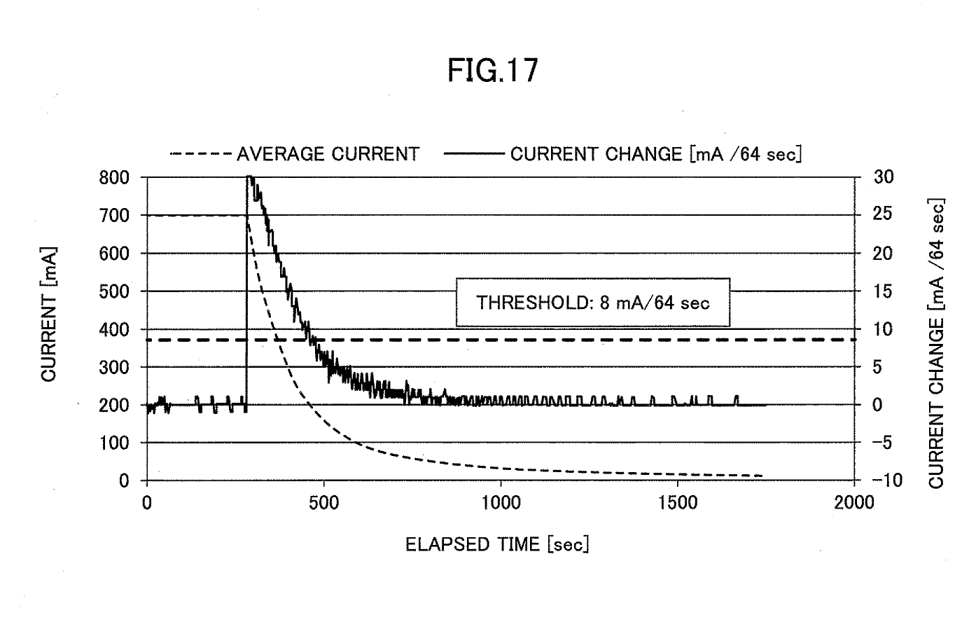

Next, FIGS. 16A and 16B are diagrams showing the state of a charging current and a charging voltage when a minute short circuit occurs during the constant-current, constant-voltage charging. FIG. 16A is a diagram showing the case in which a minute short circuit occurs during the constant-current charging. In FIG. 16A, the horizontal axis (x-axis) denotes the elapsed time in second, the right-hand side vertical axis (y-axis) denotes the charging current in mA, and the left-hand side vertical axis (y-axis) denotes the charging voltage in mV.

As shown in FIG. 16A, when a minute short circuit occurs during the constant-current charging, the state of the gradient of the rising charging voltage is partially changed.

FIG. 16B is a diagram showing the case in which a minute short circuit occurs during the constant-voltage charging. In FIG. 16B, the horizontal axis (x-axis) denotes the elapsed time in second, the right-hand side vertical axis (y-axis) denotes the charging current in mA, and the left-hand side vertical axis (y-axis) denotes the charging voltage in mV.

As shown in FIG. 16B, when a minute short circuit occurs during the constant-voltage charging, the state of the gradient of the descending charging current is partially stabilized.

In this embodiment, instead of performing the determination of a charging state based on the charging voltage and the determination of a charging state based on the charging current independently of each other, the determination of a charging state based on the combination of the charging voltage and the charging current is performed. This is done In order to prevent erroneous determination of the charging state when a minute short circuit takes place.

Specifically, by using the voltage change rate and the current change rate as shown in FIGS. 15A and 15B, the determining unit 54 in this embodiment determines the present charging state as being a constant-current charging state, when the voltage change rate is above the first threshold and the current change rate is below the second threshold. The determining unit 54 determines the present charging state as being a constant-voltage charging state, when the voltage change rate is below the first threshold and the current change rate is above the second threshold. Accordingly, even when a minute short circuit occurs during the charging as shown in FIGS. 16A and 16B, an erroneous determination of a charging state can be prevented so that it is possible to determine the charging state accurately.

When other combinations different from the above-described combination of the voltage change rate and the current change rate are detected, it is difficult to determine the charging state accurately. Hence, in such a case, the result of the determination at the previous time is maintained without change.

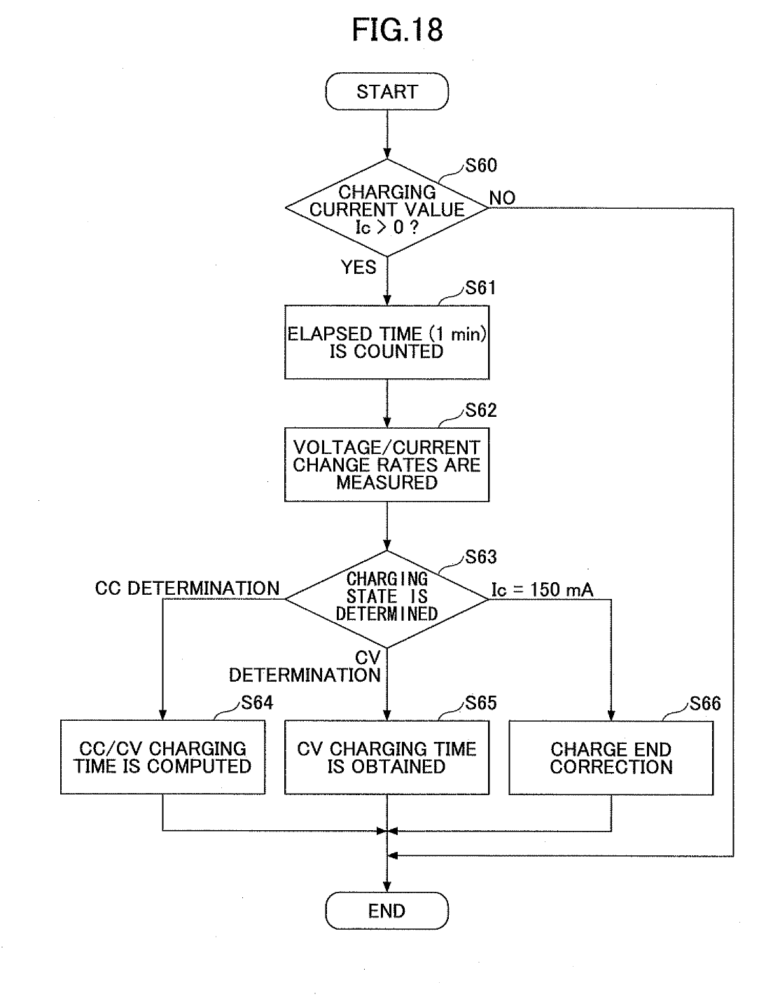

FIG. 17 is a diagram showing the state of the constant-voltage charging current at the charge end stage. In FIG. 17, the horizontal axis (x-axis) denotes elapsed time in second, the right-hand side vertical axis (y-axis) denotes the current change rate in mA/64 sec, and the left-hand side vertical axis (y-axis) denotes the charging current in mA.

The waveform of the charging current shown in FIG. 17 is a waveform of a degraded battery in which the change rate of the constant-voltage charging current falls at a low temperature (retention 88%, 0° C.). The retention is a degradation ratio of a battery which denotes the degradation ratio of the present capacity of the battery to the rated capacity. For example, the retention is represented by the formula: retention %=present battery capacity mAh/rated capacity (at fresh time) mAh×100.

As is apparent from FIG. 17, when the constant-voltage charging current value is too small, the current change rate value is also less than 8 mA/min (the second threshold). When the constant-voltage charging current value is below a predetermined value (a third threshold) and the voltage change rate and the current change rate are below the respective threshold values, the charging state of the secondary battery 20 is determined as being a constant-voltage charging state.

As described above, in this embodiment, the determining unit 54 determines the charging state of the secondary battery 20 based on the charging current value and the charging voltage value detected during charging of the secondary battery 20, in order to determine the timing to perform each of the processes for computing the fully charged time.

Specifically, the determining unit 54 starts the process of determination of a constant-current, constant-voltage charging state, for example, when the detection voltage detected by the detecting unit 51 is above 4000 mV, in order to determine a constant-current, constant-voltage charging state of the secondary battery 20.

In addition, when the voltage change rate based on the voltage and current values detected by the detecting unit 51 is above 4 mV/min (the first threshold) and the current change rate based on the detected voltage and current values is below 8 mA/min (the second threshold), the determining unit 54 determines the charging state of the secondary battery 20 as being a constant-current charging state.

In addition, when the voltage change rate based on the voltage and current values detected by the detecting unit 51 is below 4 mV/min (the first threshold) and the current change rate based on the detected voltage and current values is above 8 mA/min (the second threshold), the determining unit 54 determines the charging state of the secondary battery 20 as being a constant-voltage charging state.

In addition, when other combinations of the voltage change rate and the current change rate different from the combinations of the voltage change rate and the current change rate described above are detected, the determining unit 54 maintains the charging state at the time of the previous determination by noting that the exact charging state of the constant-current, constant-voltage charging cannot be determined.

Further, when both the voltage change rate and the current change rate described above are below the first threshold and the second threshold and the constant-voltage charging current is below a predetermined value (the third threshold) which is sufficiently small, the determining unit 54 determines the charging state of the secondary battery 20 as being a constant-voltage charging state.

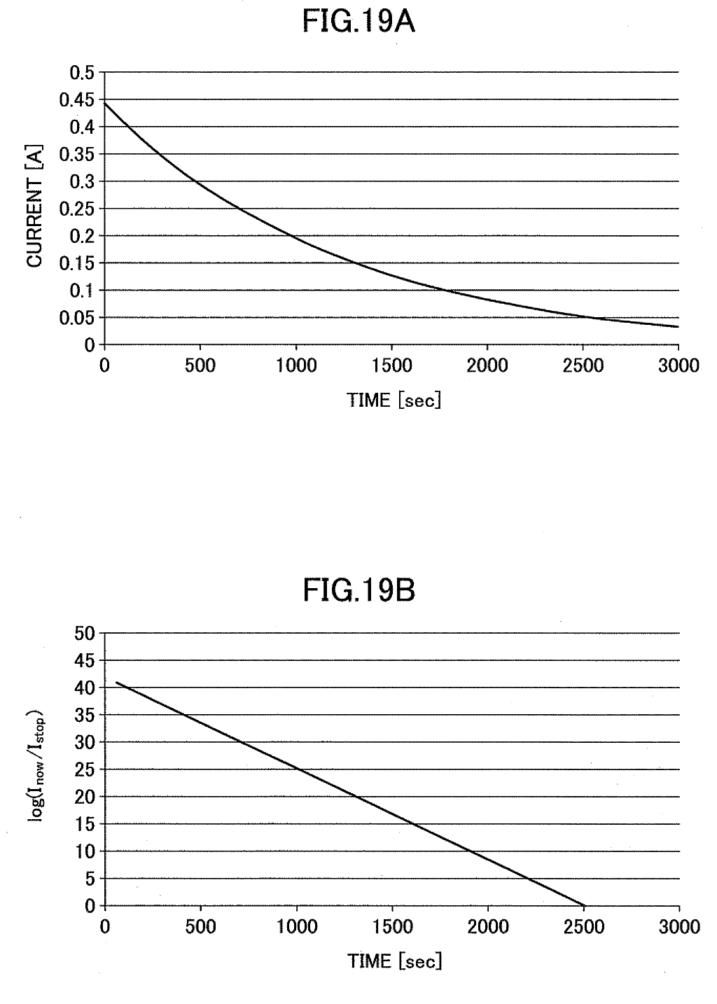

Next, the process of determination of a charging state which is performed by the determining unit 54 will be described. FIG. 18 is a flowchart for explaining the process of determination of a charging state.

As shown in FIG. 18, the determining unit 54 determines whether the charging current value Ic detected by the detecting unit 51 is larger than zero (Ic>0) (S60). When the charging current Ic is larger than zero (YES in S60), the determining unit 54 counts the elapsed time (for example, 1 min) (S61).

Subsequently, the determining unit 54 measures a current change rate of the charging current and a voltage change rate the charging voltage, both detected by the detecting unit 51 in the elapsed time of S61 (S62).

Subsequently, the determining unit 54 determines the charging state of the secondary battery 20 based on the current change rate of the charging current and the voltage change rate of the charging voltage measured in the step S62 (S63).

For example, when the voltage change rate is above 4 mV/min and the current change rate is below 8 mA/min as described above, the determining unit 54 determines the charging state of the secondary battery 20 as being a constant-current charging state, and causes the charging time computing unit 55 to compute a constant-current and constant-voltage charging time (S64).

When the voltage change rate is below 4 mV/min and the current change rate is above 8 mA/min, the determining unit 54 determines the charging state of the secondary battery 20 as being a constant-voltage charging state, and causes the constant-voltage charging time counting unit 56 to count down the constant-voltage charging time Tcv (S65).

When both the voltage change rate and the current change rate are below the first threshold and the second threshold respectively and the constant-voltage charging current Ic in this state is small enough and determined as being below the predetermined value (the third threshold, e.g., Ic=150 mA), the determining unit 54 causes the charge end correction unit 57 to perform the process of charge end correction (S66).

When the charging current value Ic is not larger than zero (Ic<=0) (NO in S60), the determining unit 54 terminates the process of FIG. 18.

Alternatively, in the process of the charging state determination described above, appropriate threshold values may be set up in the computation of the current change rate and the voltage change rate for each of intervals of the determination time. For example, the determination steps may be repeated for the duration from the time the detected changing voltage is in a vicinity of the constant-voltage charging voltage where the voltage change rate is stabilized to the time the process of charge end correction is started.

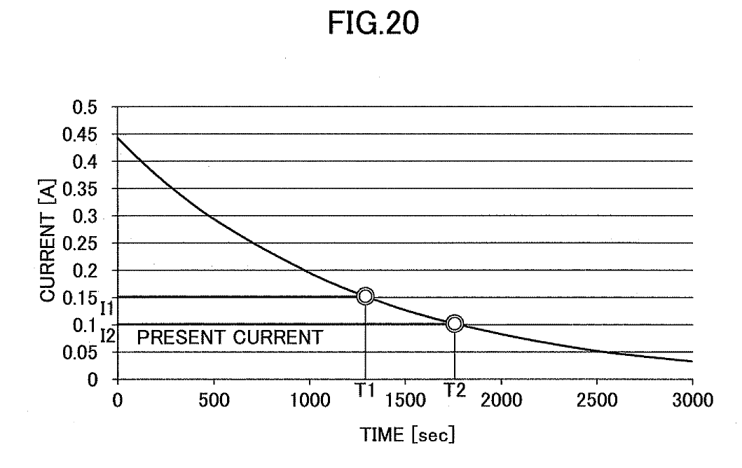

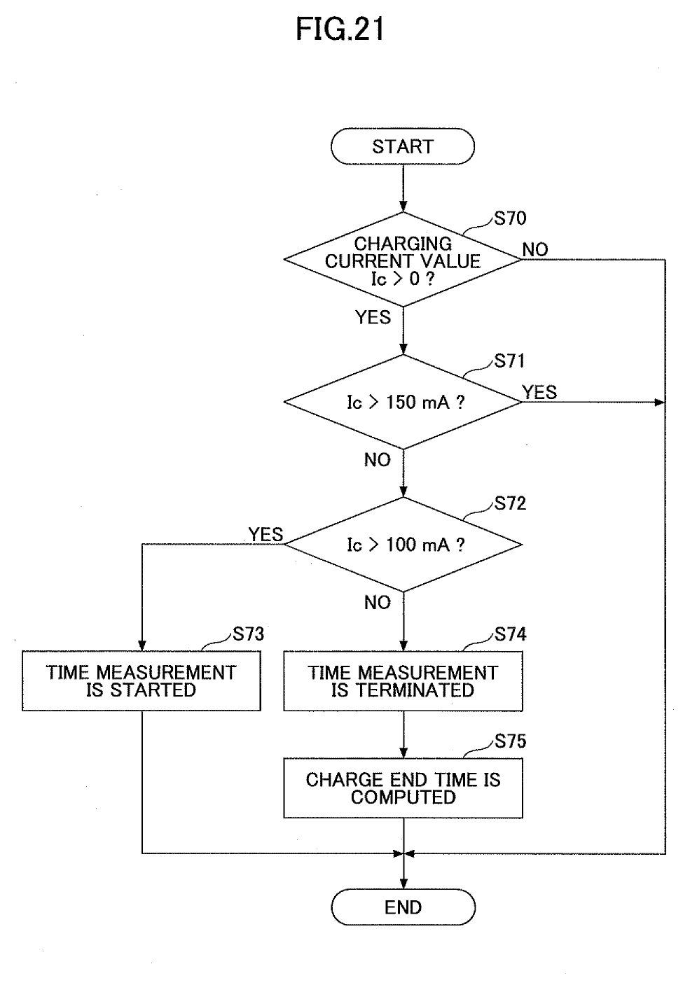

Next, the process of charge end correction performed by the charge end correction unit 57 will be described with reference to FIGS. 19A, 19B and 20.

The process of charge end correction is performed at the charge end stage to eliminate a computation error and set the last time to zero (=0).

FIGS. 19A and 19B are diagrams showing the characteristics between the constant-voltage charging current and the elapsed time at a charge end stage of a lithium ion battery at 25 deg. C.″. FIG. 19A is a diagram showing the characteristics between the constant-voltage charging current and the elapsed time at the charge end stage of the battery. In FIG. 19A, the horizontal axis (x-axis) denotes the elapsed time in second and the vertical axis (y-axis) denotes the constant-voltage charging current in A.

FIG. 19B is a diagram showing the characteristics between the logarithm of the constant-voltage charging current of FIG. 19A and the elapsed time. In FIG. 19B, the horizontal axis (x-axis) denotes the elapsed time in second and the vertical axis (y-axis) denotes the logarithm “log” of the present charging current value Inow/Istop.

As shown in FIG. 19B, the relationship between the logarithm (log(Ic)) of the constant-voltage charging current and the elapsed time is the linear characteristic. As is apparent from the characteristics shown in FIG. 19B, the constant-voltage charging time Tcv may be represented by the following formula:

Tcv=−αT×log(Inow/Istop)

As described above, Inow denotes the present charging current value. Specifically, Inow denotes the charging current value (or “I2” indicated in FIG. 20) which is predetermined as being a starting current value at the charge end stage.

FIG. 20 shows the relationship between the elapsed times T1 and T2 and the corresponding charging current values I1 and I2 as shown in FIG. 19A. In FIG. 20, the horizontal axis (x-axis) denotes the elapsed time in second and the vertical axis (y-axis) denotes the charging current in A.

The coefficient αT described above is represented by the following formula, by using the elapsed times T2 and T1 and the charging current values I1 and I2 indicated in FIG. 20:

αT=−(T2−T1)/log(I2/Istop)−log(I1/Istop).

As is apparent from the characteristics shown in FIG. 19B, the remaining charging time at the time of charge end correction (the charge end time) may be represented by the following formula by using the charging current values I2 and I1 at the two points the elapsed times T2 and T1:

Charge end time=−{(T2−T1)/[log(I2/Istop)−log(I1/Istop)]}×log(Inow/Istop).

When the timing to compute the coefficient αT described above is considered as the time of detection of the charging current value I1 and the charging current value I2 as shown in FIG. 20, the charging current values I1 and I2 and the value of the present current Inow are constant, the denominator of the coefficient term of the above formula is constant, and the charge end time may be represented by the following formula.

Charge end time=−{(T2−T1)/α log×[β log−log(Istop)] (5)

For example, the charge end time is computed as follows:

Charge end time=−{(102 min−95.6 min)/(−0.18)×(2−1.78)=7.8 min.

The coefficients (α log, β log) which indicate the above characteristics are stored in the recording unit 52 as characteristic data.

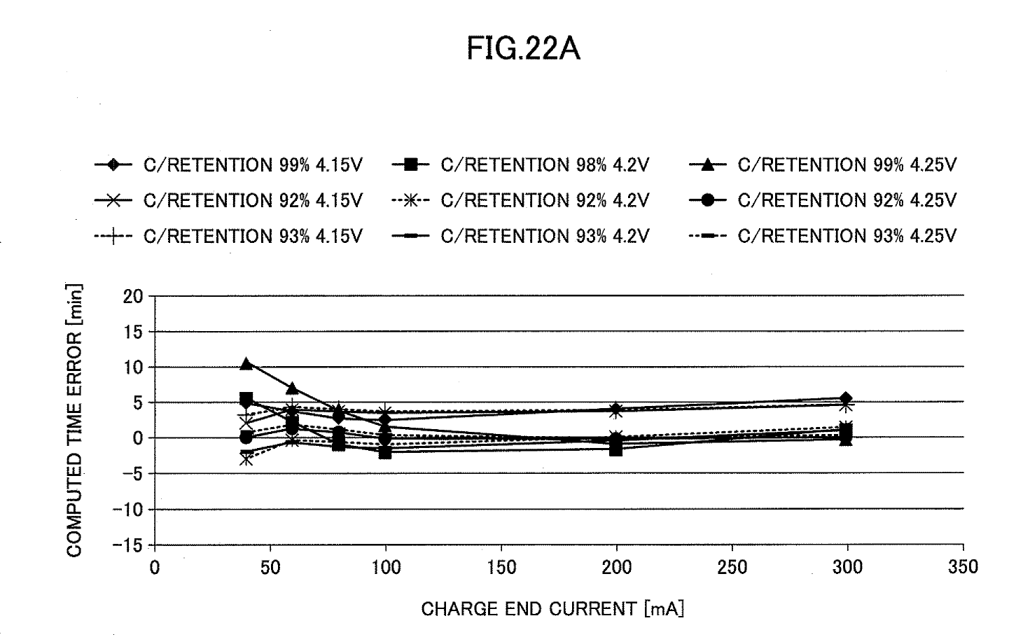

Next, the process of charge end correction which is performed by the charge end correction unit 57 will be described. FIG. 21 is a flowchart for explaining the process of charge end correction.

As shown in FIG. 21, the charge end correction unit 57 determines whether the charging current value Ic detected by the detecting unit 51 is larger than zero (Ic>0) (S70). When the charging current value Ic is larger than zero (YES in S70), the charge end correction unit 57 determines whether the charging current value Ic is larger than 150 mA (Ic>150 mA) (S71).

When the charging current value Ic is not larger than 150 mA (NO in S71), the charge end correction unit 57 determines whether the charging current value Ic is larger than 100 mA (Ic>100 mA) (S72).

When the charging current value Ic is above 100 mA and below 150 mA (YES in S72), the charge end correction unit 57 starts time measurement (S73). Specifically, in this case, the time T1 at the instant of detection of the charging current value Ic1 indicated in FIG. 20, and the time T2 at the instant of detection of the charging current value Ic2 are measured and stored in the recording unit 52.

When the charging current value Ic is below than 100 mA (NO in S72), the charge end correction unit 57 terminates time measurement (S74), and computes the charge end time for performing the process of charge end correction by the above formula (5) (S75). Then, the process of FIG. 21 is terminated.

When it is determined that the charging current value Ic is not larger than zero (Ic<=0) (NO in S70), the charge end correction unit 57 does not perform the steps S71-S75, and the process of FIG. 21 is terminated.

In the step S75 described above, the charge end correction unit 57 acquires each characteristic data (α log, β log), the time of T2−T1, and the charge end current Istop which are stored in the recording unit 52, and computes the charge end time by the above formula (5). After the computation is performed, the charge end correction unit 57 counts down the computed charge end time.

Next, the accuracy of computation of the estimated time computed by the charging time computing unit 55 in this embodiment will be described.

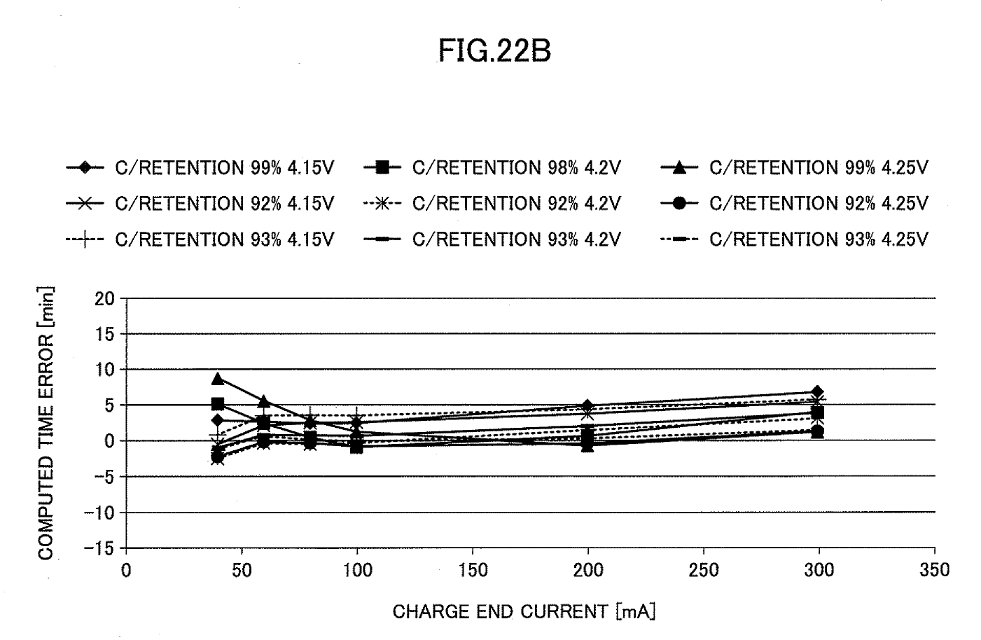

FIGS. 22A and 22B are diagrams for explaining the accuracy of computation of the estimated time computed by the charging time computing unit. In FIGS. 22A and 22B, the horizontal axis (x-axis) denotes the charge end current in mA, and the vertical axis (y-axis) denotes the computed time error in minute.

FIG. 22A shows the example at the measurement temperature 25° C. and the path resistance 40 mΩ, and FIG. 22B shows the example at the measurement temperature 25° C. and the path resistance 80 mΩ. The computed time error along the vertical axis (y-axis) of FIG. 22A and FIG. 22B denotes the time (error) which is obtained by subtracting the actually measured charging time of the battery from the estimated time computed by the charging time computing unit 55.

As is apparent from FIGS. 22A and 22B, when the computed time error to the change of the charge end current is computed for the cases in which the capacity retention and the charging voltage of the secondary battery 20 are different from each other, the computed time errors of all the cases are below 10 minutes.

Next, the accuracy of computation of the charging time corrected by the charge end correction unit 57 in this embodiment will be described.

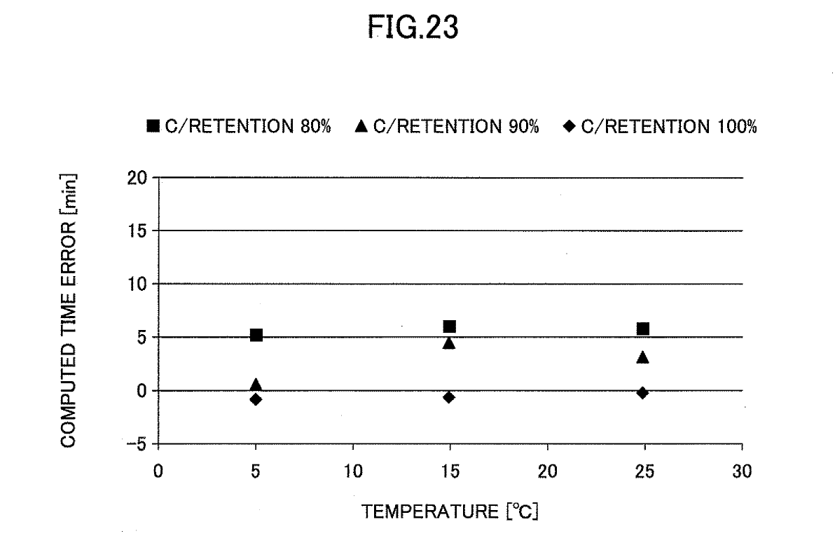

FIG. 23 is a diagram for explaining the accuracy of computation of the charging time corrected by the charge end correction unit 57. In FIG. 23, the horizontal axis (x-axis) denotes the temperature in ° C., and the vertical axis (y-axis) denotes the computed time error in min.

As shown in FIG. 23, in the cases in which the charge end current is 60 mA and the capacity retention of the secondary battery 20 is 80%, 90% and 100% respectively, the computed time error to the change of the temperature is computed. The computed time errors of these cases are on the order of 5 minutes.

Next, changes of the computed time by switching of the charging time computation in the fully charged time computation process of this embodiment will be described.

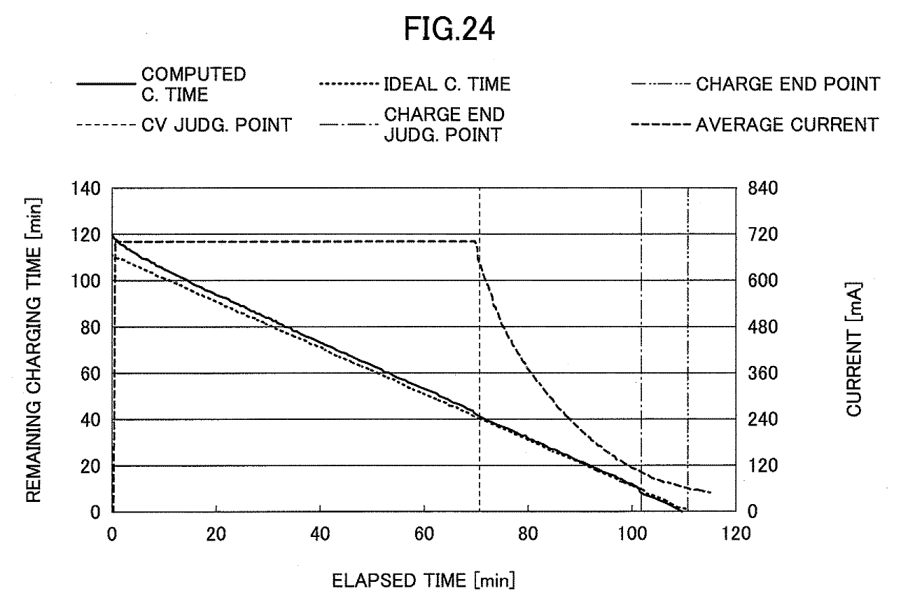

FIG. 24 is a diagram for explaining changes of the computed time by switching of the charging time computation. In FIG. 24, the horizontal axis (x-axis) denotes the elapsed time in minute, the right-hand side vertical axis (y-axis) denotes the charging current in mA, and the left-hand side vertical axis (y-axis) denotes the remaining charging time in minute.

As shown in FIG. 24, the computed charging time in the fully charged time computation process of this embodiment is changed as follows. The remaining charging time to the elapsed time is computed to be in conformity with the measured charging time (ideal charging time). After the constant-voltage judgment point of constant-voltage charging is reached, the remaining charging time mostly overlaps with the ideal charging time. At the charge end point, the remaining charging time is almost zero simultaneously with the end of the charging.

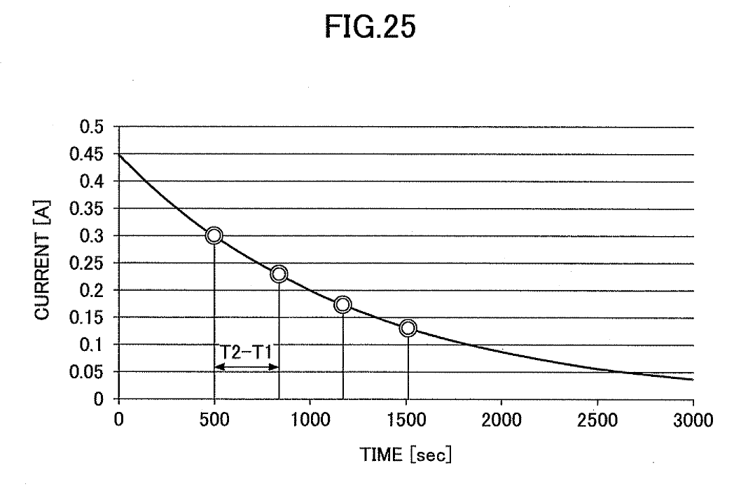

Next, a modification of the charge end correction process of this embodiment will be described. FIG. 25 is a diagram for explaining the modification of the charge end correction processing of this embodiment. In FIG. 25, the horizontal axis (x-axis) denotes the elapsed time in second and the vertical axis (y-axis) denotes the charging current in A.

In the above-described charge end correction process of FIG. 20, when the predetermined charging current (Ic1, Ic2) is detected, the time (T1, T2) at the time of the charging current detection is stored and the charge end time is computed.

On the other hand, in the modification shown in FIG. 25, the charge end time is intermittently computed at intervals of a predetermined time (T2−T1), and the computed charge end time is corrected. The charge end time may be represented by the formula which is the same as the above-described formula:

Charge end time=−{(T2−T1)/[log(Ic2/Istop)−log(Ic1/Istop)]}×log(Inow/Istop).

In this modification, the interval of (T2−T1) is set to a constant time, and the computation of the charge end time by the above formula performed at intervals of the constant time is possible.

In the modification, the charge end time can be computed at intervals of the time, the gradient of the charging current in FIG. 25 can be easily estimated, and it is possible to improve the accuracy of computation of the charge end time.

As described in the foregoing, by computing the permissible charging capacity according to the state of the secondary battery, it is possible to improve the accuracy of computation of the fully charged time of the secondary battery. Specifically, the permissible charging capacity can be computed while taking into consideration the path resistance, the charging voltage and the charge end current which are needed in actual use. The estimated fully charged time of the secondary battery is computed by totaling the constant-current charging time Tcc and the constant-voltage charging time Tcv which have been computed individually, and it is possible to improve the accuracy of computation of the fully charged time. By correcting the estimated time in the charge end stage, it is possible to provide the estimated remaining time with good accuracy.

Therefore, according to the present disclosure, the exact fully charged time for completing the charging of the secondary battery can be computed, and it is possible to improve the usability of the product utilizing the secondary battery. When the actual charging time is longer than the estimated time computed, or when the actual charging capacity is larger than the permissible charging capacity computed, an unusual state of the secondary battery can be easily detected, which will enable the safe operation of the secondary battery. By storing the estimated charging time in the early stage at the standard temperature, it is possible to grasp the degradation state of the secondary battery from the actual charging time. By storing the charging capacity of the secondary battery actually, even when it is difficult to compute the battery resistance of the secondary battery, it is possible to compute the battery resistance of the secondary battery by the inverse computation.

As described in the foregoing, according to the present disclosure, it is possible to improve the accuracy of computation of the fully charged time of a secondary battery by computing the permissible charging capacity according to the state of the secondary battery.

The present disclosure is not limited to the above-described embodiments, and variations and modifications may be made without departing from the scope of the present disclosure.

What is claimed is:

1. A battery monitoring device comprising:
a detecting unit to detect a voltage value, a current value and a temperature of a secondary battery;
a charging time computing unit to compute a charging time of the battery by using the voltage value, the current value and the temperature detected by the detecting unit; and
a determining unit to determine a charging state of the battery,
wherein the charging time computing unit is configured to compute a charging time of the battery based on a first charging ratio, a constant-current charging ratio and a second charging ratio,
the first charging ratio corresponding to a predetermined charge end current and being computed by using a path resistance of the battery computed based on the voltage and current values detected by the detecting unit during constant-voltage charging of the battery, a charging voltage value of the battery, and an internal resistance value at a present temperature of the battery,
the constant-current charging ratio being computed by using the first charging ratio, and
the second charging ratio corresponding to a charge end current specific to a charging circuit to charge the battery and being computed by using the first charging ratio.

2. The battery monitoring device according to claim 1, wherein the charging time computing unit is configured to
compute a constant-current charging time based on the first charging ratio and a charging current value detected by the detecting unit during constant-current charging of the battery,
compute a constant-voltage charging time based on the charging current value detected by the detecting unit during constant-current charging of the battery, the constant-current charging ratio and the second charging ratio, and
compute the fully charged time of the battery by adding the constant-voltage charging time to the constant-current charging time.

3. A battery monitoring device according to claim 1, further comprising a charge end correction unit to
compute, when the charging state of the battery is determined as being a constant-voltage charging state by the determining unit and a charging current value detected by the detecting unit is below a predetermined value, a charge end time by using a predetermined current value detected by the detecting unit and the specific charge end current, and
correct the fully charged time of the battery by using the computed charge end time.

4. The battery monitoring device according to claim 1, wherein the determining unit is configured to acquire a voltage change rate and a current change rate of the battery and a predetermined current value of the battery based on the values detected by the detecting unit, and determine the charging state of the battery by using the voltage change rate and the current change rate of the battery and the predetermined current value.

5. A battery monitoring method performed by a battery monitoring device including a detecting unit to detect a voltage value, a current value and a temperature of a secondary battery, a charging time computing unit to compute a charging time of the battery by using the voltage value, the current value and the temperature detected by the detecting unit, and a determining unit to determine a charging state of the battery, comprising:
acquiring a path resistance of the battery based on the voltage and current values detected by the detecting unit during constant-voltage charging of the battery;
computing a first charging ratio corresponding to a predetermined charge end current by using the acquired path resistance of the battery, a charging voltage value of the battery, and an internal resistance value at a present temperature of the battery;
computing a constant-current charging ratio by using the first charging ratio;
computing a second charging ratio corresponding to a charge end current specific to a charging circuit to charge the battery by using the first charging ratio; and
computing a fully charged time of the battery based on the first charging ratio, the constant-current charging ratio and the second charging ratio.

6. The battery monitoring method according to claim 5, wherein the computing the fully-charged time of the battery includes:
computing a constant-current charging time based on the first charging ratio and a charging current value detected by the detecting unit during constant-current charging of the battery;
computing a constant-voltage charging time based on the charging current value detected by the detecting unit during constant-current charging of battery, the constant-current charging ratio and the second charging ratio; and
computing the fully charged time of the battery by adding the constant-voltage charging time to the constant-current charging time.

7. The battery monitoring method according to claim 5, further comprising:
computing, when the charging state of the battery is determined as being a constant-voltage charging state by the determining unit and a charging current value detected by the detecting unit is below a predetermined value, a charge end time by using a predetermined current value detected by the detecting unit and the specific charge end current; and
correcting the fully charged time of the battery by using the computed charge end time.

8. The battery monitoring method according to claim 5, further comprising:
acquiring, by the determining unit, a voltage change rate and a current change rate of the battery and a predetermined current value of the battery based on the values detected by the detecting unit; and
determining, by the determining unit, the charging state of the battery by using the voltage change rate and the current change rate of the battery and the predetermined current value.
